(19) United States
(12) Patent Application Publication
(10) Pub. No.: US 2026/0238186 A1
(43) Pub. Date: Aug. 13, 2026

(54) TRANSVERSELY-EXCITED BULK ACOUSTIC RESONATOR WITH NON-LINEAR CHIRPING PROFILE

(71) Applicant: Murata Manufacturing Co., Ltd., Nagaokakyo-shi (JP)

(72) Inventors: Bryant GARCIA, Mississauga, CA (US); John Koulakis, Los Angeles, CA (US)

(21) Appl. No.: 19/461,834

(22) Filed: Jan. 28, 2026

Related U.S. Application Data
(60) Provisional application No. 63/755,673, filed on Feb. 7, 2025.

(51) Int. Cl. H03H 9/17; H03H 9/13; H03H 9/60

(52) U.S. Cl. CPC H03H 9/173; H03H 9/133; H03H 9/605

(57) ABSTRACT

An acoustic resonator is provided that includes a piezoelectric layer; and an IDT on a surface of the piezoelectric layer. The IDT includes three sections of interleaved fingers that alternately extend from a first busbar and a second busbar. Each of the sections include a respective length that includes at least two pairs of interleaved fingers. At least the last section of the IDT comprises a chirping profile that is non-linear, such that a variation of the mark and/or a pitch of the section is non-linear across its length of the at least one section. A first mathematical derivative of the non-linear chirping profile of the last section is a same sign that increases monotonically, and a second mathematical derivative of the non-linear chirping profile of the last section is nonzero and a same sign increasing exponentially.

### CROSS REFERENCE TO RELATED APPLICATIONS

The current patent application claims priority to U.S. Patent Provisional No. 63/755,673, filed Feb. 7, 2025, the entire contents of which are hereby incorporated by reference.

### TECHNICAL FIELD

This disclosure relates to radio frequency filters using acoustic wave resonators, and more specifically, to filters for use in communications equipment.

### BACKGROUND

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “passband” of the filter. The range of frequencies stopped by such a filter is referred to as the “stop-band” of the filter. A typical RF filter has at least one passband and at least one stop-band. Specific requirements on a passband or stop-band may depend on the specific application. For example, in some cases a “passband” may be defined as a frequency range where the insertion loss of a filter is better than a defined value such as 1 dB, 2 dB, or 3 dB, while a “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

Performance enhancements to the RF filters in a wireless system can have a broad impact to system performance. Improvements in RF filters can be leveraged to provide system performance improvements, such as larger cell size, longer battery life, higher data rates, greater network capacity, lower cost, enhanced security, higher reliability, etc. These improvements can be realized at many levels of the wireless system both separately and in combination, for example, at the RF module, RF transceiver, mobile or fixed sub-system, or network levels. As the demand for RF filters operating at higher frequencies continues to increase, there is a need for improved filters that can operate at different frequency bands while also improving the manufacturing processes for making such filters.

The transversely-excited film bulk acoustic resonator (XBAR) is an acoustic resonator structure for use in microwave filters. An XBAR resonator typically comprises an interdigital transducer (IDT) formed on a thin floating layer, or diaphragm, of a single-crystal piezoelectric material. The IDT includes a first set of parallel fingers, extending from a first busbar and a second set of parallel fingers extending from a second busbar. The first and second sets of parallel fingers are interleaved. A microwave signal applied to the IDT excites a shear primary acoustic wave in the piezoelectric diaphragm. XBAR resonators provide very high electromechanical coupling and high frequency capability. XBAR resonators may be used in a variety of RF filters including band-reject filters, bandpass filters, duplexers, and multiplexers. XBARs are well suited for use in filters for communications bands with frequencies above 3 GHz.

### SUMMARY

According to exemplary aspects, a bulk acoustic resonator is provided that includes an interdigital transducer (IDT) having one or more sections of interleaved fingers with a nonlinear chirping profile in order to reduce spurious magnitudes in the acoustic resonator device for small signal or large signal performance gains.

More specifically, in an exemplary aspect, an acoustic resonator is provided that includes a piezoelectric layer; and an interdigital transducer (IDT) on a surface of the piezoelectric layer, the IDT having a plurality of interleaved fingers that alternately extend from a first busbar and a second busbar. In this aspect, the IDT comprises at least three sections that includes a first section, a last section and a center section disposed between the first and last sections in a length direction of the IDT. Each of the at least three sections comprise a respective length that includes at least two pairs of interleaved fingers. Moreover, at least one section of the first section and the last section of the IDT comprises a chirping profile that is non-linear, such that a variation of at least one of a mark and a pitch of the at least one section is non-linear across the length of the at least one section, the mark being a width of the at least two pairs of interleaved fingers and the pitch being a center-to-center spacing between each pair of interleaved fingers. Yet further, a first mathematical derivative of the non-linear chirping profile of the at least one section is a same sign that increases monotonically, and a second mathematical derivative of the non-linear chirping profile of the at least one section is nonzero and a same sign that is increases exponentially.

In another exemplary aspect, both the first section and the last section of the IDT comprise a non-linear chirping profile that is concave out, such that the variation of the at least one of the mark and the pitch of each of the first and last sections is flatter as the respective section extends towards the center section and steeper as the respective section extends away from the center section.

In another exemplary aspect, the variation of the at least one of the mark and the pitch of both the first section and last section is represented by A(x), where

$$A ( x ) = \frac{A}{2} a tanh ( x tanh ( 2 π k ) ) ,$$

where k>0 and measures a curvature of the non-linear chirping profile, and x is between −1 and +1.

In another exemplary aspect, both the first section and the last section of the IDT comprise a non-linear chirping profile that is concave in, such that the variation of the at least one of the mark and the pitch of each of the first and last sections is steeper towards the center section and flatter as the respective section extends away from the center section. Moreover, in this aspect, the variation of the at least one of the mark and the pitch of both the first section and last section

can be represented by A(x), where

$$A ( x ) = \frac{A}{2} \frac{tanh ( 2 π kx )}{tanh ( 2 π k )} ,$$

where k>0 and measures a curvature of the non-linear chirping profile, and x is between −1 and +1.

In another exemplary aspect, each of the center section and the at least one section comprise a plurality of subsections that each have at least three interleaved fingers that have at least one of a constant pitch and a constant mark therein.

In another exemplary aspect, a number of interleaved fingers of the at least one section comprises approximately 25% or less of a total number of fingers of the plurality of interleaved fingers of the IDT. Moreover, in this aspect, the variation of the pitch of the at least one section increases exponentially and the variation of the pitch of the center section can be comparatively linear relative to the variation of pitch of the at least one section. Yet further, the mark can be substantially constant across the length of the IDT. In addition, the center section can comprise a chirping profile that is substantially linear.

In another exemplary aspect, an acoustic resonator is provided that includes a piezoelectric layer; and an interdigital transducer (IDT) on a surface of the piezoelectric layer, the IDT having a plurality of interleaved fingers that alternately extend from a first busbar and a second busbar. In this aspect, the IDT comprises a plurality of sections that each have a respective length that includes at least two pairs of interleaved fingers, the IDT has an asymmetric chirping profile, such that a variation of at least one of a mark and a pitch of a first section of the plurality of sections is non-linear across the length of the first section, the mark being a width of the at least two pairs of interleaved fingers and the pitch being a center-to-center spacing between each pair of interleaved fingers, and the variation of the at least one of the mark and the pitch has a less than 25% effect on a primarily excited main acoustic mode of the acoustic resonator in comparison to a 1:1 effect of at least one of a pitch and a mark on a mode other than the primarily excited main acoustic mode.

In another exemplary aspect, a second section of the plurality of sections of the IDT has a pitch or mark profile that is substantially linear and different than the asymmetric chirping profile of the first section. In this aspect, the plurality of sections of the IDT can comprise the first section, the second section and a third section, with the second section being a center section between the first and third sections in a length direction of the IDT. Yet further, both the first section and the third section of the IDT can comprise a non-linear chirping profile that is concave out, such that the variation of the at least one of the mark and the pitch of each of the first and third sections is flatter as the respective section extends towards the center section and steeper as the respective section extends away from the center section.

In another exemplary aspect, both the first section and the third section of the IDT comprise a non-linear chirping profile that is concave in, such that the variation of the at least one of the mark and the pitch of each of the first and third sections is steeper towards the center section and flatter as the respective section extends away from the center section.

In another exemplary aspect, the pitch or mark profile of the second section is substantially linear and the variation of at least one of a mark and a pitch of the first section increases as the first extends away from the second section in a length direction of the IDT, and a first mathematical derivative of the asymmetric chirping profile of the first section is a same sign that increases monotonically, and a second mathematical derivative of the asymmetric chirping profile of the first section is nonzero and a same sign that is increases exponentially.

In another exemplary aspect, a number of interleaved fingers of the first section comprises approximately 25% or less of a total number of fingers of the plurality of interleaved fingers of the IDT, and the variation of the pitch of the at first section increases exponentially and the variation of the pitch of the second section is comparatively linear relative to the variation of pitch of the at least one section.

In another exemplary aspect, the first section comprises a plurality of subsections that each have at least three interleaved fingers that have at least one of a constant pitch and a constant mark therein.

In yet another exemplary aspect, an acoustic resonator is provided that includes a piezoelectric layer; and an interdigital transducer (IDT) on a surface of the piezoelectric layer, the IDT having a plurality of interleaved fingers that alternately extend from a first busbar and a second busbar. In this aspect, the IDT comprises a first section and a second section that each have a respective length that includes at least two pairs of interleaved fingers, the interleaved fingers of each of the first section and the second section have an asymmetric chirping profile, such that a variation of at least one of a mark and a pitch is non-linear across the length of the respective section, the mark being a width of the at least two pairs of interleaved fingers and the pitch being a center-to-center spacing between each pair of interleaved fingers, and the variation of the at least one of the pitch and the mark of each of the first and second sections increases exponentially as the respective length of each of the first and second sections extend towards each other, such that the IDT collectively including the first and second sections has a symmetric chirping profile.

### BRIEF DESCRIPTION OF THE DRAWINGS

The accompanying drawings, which are incorporated into and form a part of this specification, illustrate one or more example aspects of the present disclosure and, together with the detailed description, serve to explain their principles and implementations.

FIG. 1A includes a schematic plan view and a schematic cross-sectional view of a transversely-excited film bulk acoustic resonator (XBAR).

FIG. 1B shows a schematic cross-sectional view of an alternative configuration of an XBAR.

FIG. 2A is an expanded schematic cross-sectional view of a portion of the XBAR of FIG. 1A.

FIG. 2B is an expanded schematic cross-sectional view of an alternative configuration of the XBAR of FIG. 1A.

FIG. 2C is an expanded schematic cross-sectional view of another alternative configuration of the XBAR of FIG. 1A.

FIG. 2D is an expanded schematic cross-sectional view of another alternative configuration of the XBAR of FIG. 1A.

FIG. 2E is an expanded schematic cross-sectional view of a portion of a solidly-mounted XBAR (SM XBAR).

FIG. 3A is a schematic cross-sectional view of an XBAR according to an exemplary aspect.

FIG. 3B is an alternative schematic cross-sectional view of an XBAR according to an exemplary aspect.

FIG. 4 is a graphic illustrating a shear horizontal acoustic mode in an XBAR.

FIG. 5A is a schematic block diagram of a filter using XBARs of FIGS. 1A and/or 1B.

FIG. 5B is a schematic diagram of a radio frequency module that includes an acoustic wave filter device according to an exemplary aspect.

FIG. 6 is a plan view of a multi-mark multi-pitch IDT according to an exemplary aspect.

FIG. 7A is a graph of IDT chirping profiles as a function of position along a length of IDTs according to exemplary aspects.

FIG. 7B illustrates a graph showing the performance difference between the chirping profiles shown in FIG. 7A.

FIG. 7C illustrates a graph illustrating a ratio on an effect of chirping on different vibrational modes of an acoustic resonator.

FIG. 8A is a graph of an IDT chirping profile as a function of position along a length of an IDT according to another exemplary aspect.

FIG. 8B illustrates a plot showing acoustic intensity relative to a graph illustrating which subsection(s) of the IDT should have the nonlinear chirping configuration according to the exemplary aspect.

FIG. 8C illustrates three graphs showing the pitch profile p(x), the first derivative and the second derivative of the profile p(x) of the IDT having the chirping profile shown in the graph in FIG. 8A.

FIG. 9A is a graph of an IDT chirping profile as a function of position along a length of an IDT according to another exemplary aspect.

FIG. 9B is a graph of an IDT chirping profile as a function of position along a length of an IDT according to another exemplary aspect.

FIG. 9C illustrates three graphs showing the pitch profile p(x), the first derivative and the second derivative of the profile p(x) of the IDT having the chirping profile shown in the graph in FIG. 9A.

FIG. 10 illustrates a graph that illustrates the impact on the A1 mode measured as the reduction in resonance Q that trades with reduction in spur amplitude.

Throughout this description, elements appearing in figures are assigned three-digit or four-digit reference designators, where the two least significant digits are specific to the element and the one or two most significant digits are the figure number where the element is first introduced. An element that is not described in conjunction with a figure may be presumed to have the same characteristics and function as a previously described element having the same reference designator.

### DETAILED DESCRIPTION

Various aspects of the disclosed bulk acoustic resonator, a filter device, a radio frequency module, and method of manufacturing the same are now described with reference to the drawings, wherein like reference numerals are used to refer to like elements throughout. In the following description, for purposes of explanation, numerous specific details are set forth in order to promote a thorough understanding of one or more aspects of the disclosure. It may be evident in some or all instances, however, that any aspects described below can be practiced without adopting the specific design details described below. In other instances, well-known structures and devices are shown in block diagram form in order to facilitate description of one or more aspects. The following presents a simplified summary of one or more aspects of the invention in order to provide a basic understanding thereof.

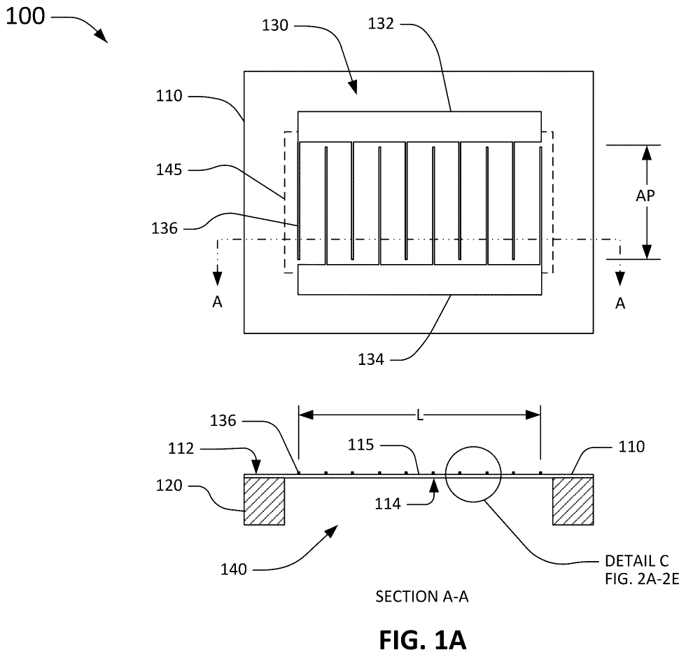

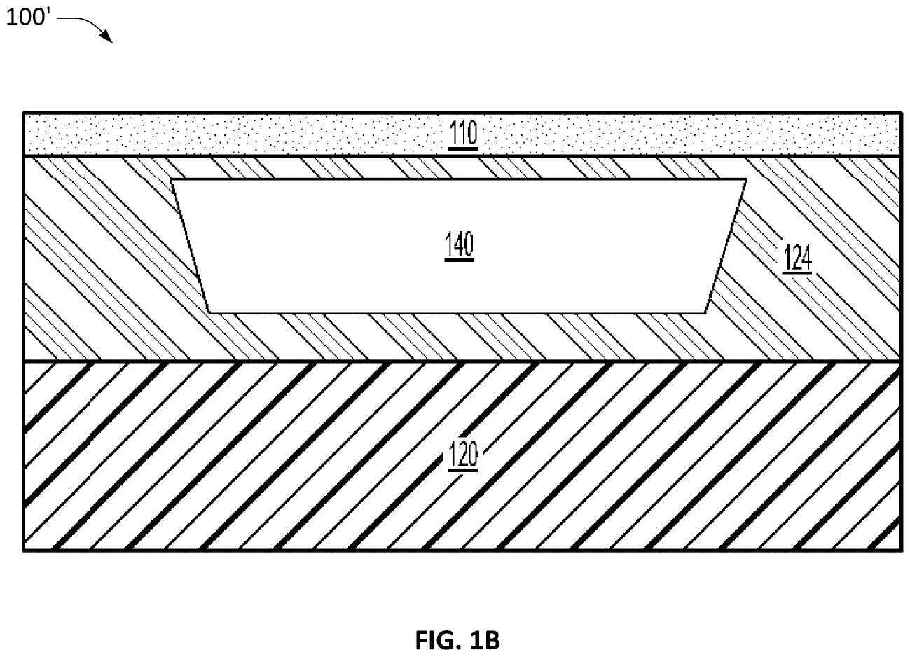

FIG. 1A shows a simplified schematic top view and an orthogonal cross-sectional view of a bulk acoustic resonator device, namely a transversely excited film bulk acoustic resonator (XBAR) 100. XBAR resonators, such as the resonator 100, may be used in a variety of RF filters including band-rejection filters, bandpass filters, duplexers, and multiplexers. XBARs are particularly suited for use in filters for communications bands with frequencies above 3 GHz.

In general, the XBAR 100 includes a conductor pattern (e.g., a thin film metal layer) formed at one or both surfaces of a piezoelectric layer 110 (herein piezoelectric plate or piezoelectric layer may be used interchangeably) having parallel front side 112 and a back side 114, respectively (also referred to generally first and second surfaces, respectively). It should be appreciated that the term “parallel” generally refers to the front side 112 and back side 114 being opposing to each other and that the surfaces are not necessarily planar and exactly parallel to each other. For example, due to the manufacturing variances result from the deposition process, the front side 112 and back side 114 may have undulations of the surface as would be appreciated to one skilled in the art. Moreover, the term “substantially” as used herein is used to describe when components, parameters and the like are generally the same (i.e., “substantially constant”), but may vary slightly (e.g., within an acceptable threshold or percentage) in practice due to possible manufacturing variances as would be appreciated to one skilled in the art. For purposes of this disclosure, the use of the term “or” in the claims is used to mean “and/or” unless explicitly indicated to refer to alternatives only or if the alternatives are mutually exclusive.

According to an exemplary aspect, the piezoelectric layer can be a thin single-crystal layer of a piezoelectric material, such as lithium niobate, lithium tantalate, lanthanum gallium silicate, gallium nitride, or aluminum nitride. It should be appreciated that the term “single-crystal” does not necessarily mean entirely of a uniform crystalline structure and may include impurities due to manufacturing variances as long as the crystal structure is within acceptable tolerances. The piezoelectric layer is cut such that the orientation of the X, Y, and Z crystalline axes with respect to the front and back sides is known and consistent. In the examples described herein, the piezoelectric layers are Z-cut, which is to say the Z axis is normal to the front and back sides 112, 114. However, XBARs may be fabricated on piezoelectric layers with other crystallographic orientations including rotated Z-cut, Y-cut and rotated YX cut.

The Y-cut family, such as 120Y and 128Y, are typically referred to as 120YX or 128YX, where the “cut angle” is the angle between the y axis and the normal to the layer. The “cut angle” is equal to β+90°. For example, a layer with Euler angles [0°, 30°, 0°] is commonly referred to as “120° rotated Y-cut” or “120Y.” Thus, the Euler angles for 120YX and 128YX are (0, 120−90,0) and (0, 128-90,0) respectively. A “Z-cut” is typically referred to as a ZY cut and is understood to mean that the layer surface is normal to the Z axis but the wave travels along the Y axis. The Euler angles for ZY cut are (0, 0, 90).

The back side 114 of the piezoelectric layer 110 may be at least partially supported by a surface of the substrate 120 except for a portion of the piezoelectric layer 110 that forms a diaphragm 115 that is over (e.g., spanning or extending over) a cavity 140 in one or more layers below the piezoelectric layer 110 such as one or more intermediate layers above or in the substrate. In other words, the back side 114 of the piezoelectric layer 110 can be coupled or connected either directly or indirectly, via one or more intermediate layers (e.g., a dielectric layer, such as a silicon oxide layer), to a surface of the substrate 120. Moreover, the phrase “supported by” or “attached” may, as used herein interchangeably, mean attached directly, attached indirectly, mechanically supported, structurally supported, or any combination thereof. The portion of the piezoelectric layer that is over (e.g., spanning or extending over) the cavity can be referred to herein as a “diaphragm” 115 due to its physical resemblance to the diaphragm of a microphone. As shown in FIG. 1A, the diaphragm 115 is contiguous with the rest of the piezoelectric layer 110 around all of a perimeter 145 of the cavity 140. In this context, “contiguous” means “continuously connected without any intervening item”. However, the diaphragm 115 can be configured with at least 50% of the edge surface of the diaphragm 115 coupled to the edge of the piezoelectric layer 110 in an exemplary aspect.

According to the exemplary aspect, the substrate 120 is configured to provide mechanical support to the piezoelectric layer 110. The substrate 120 may be, for example, silicon, sapphire, quartz, or some other material or combination of materials. The back side 114 of the piezoelectric layer 110 may be bonded to the substrate 120 using a wafer bonding process. Alternatively, the piezoelectric layer 110 may be grown on the substrate 120 or supported by, or attached to, the substrate in some other manner.

For purposes of this disclosure, “cavity” has its conventional meaning of “an empty space within a solid body.” The cavity 140 may be a hole completely through the substrate 120 (as shown in Section A-A), a hole within a dielectric layer (as shown in FIG. 1B), or a recess in the substrate 120. The cavity 140 may be formed, for example, by selective etching of the substrate 120 before or after the piezoelectric layer 110 and the substrate 120 are attached, either directly or indirectly.

As shown, the conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved with each other that can be “substantially” parallel to each other due to minor variations, such as due to manufacturing tolerances, for example. At least a portion of the interleaved fingers overlap for a distance AP, commonly referred to as the “aperture” of the IDT. The center-to-center distance L between the outermost fingers of the IDT 130 is the “length” of the IDT.

In the example of FIG. 1A, the IDT 130 is at the surface of the front side 112 (e.g., the first surface) of the piezoelectric layer 110. However, as discussed below, in other configurations, the IDT 130 may be at the surface of the back side 114 (e.g., the second surface) of the piezoelectric layer 110 or at both the surfaces of the front and back sides 112, 114 of the piezoelectric layer 110, respectively.

The first and second busbars 132, 134 are configured as the terminals of the XBAR 100 with the plurality of interleaved fingers extending therefrom. In operation, a radio frequency signal or microwave signal applied between the two busbars 132, 134 of the IDT 130 primarily excites an acoustic mode (i.e., a primarily shear acoustic mode) within the piezoelectric layer 110. As will be discussed in further detail, the primarily excited shear acoustic mode is a bulk shear mode or bulk acoustic wave where acoustic energy of a bulk shear acoustic wave is excited in the piezoelectric layer 110 by the IDT 130 and propagates along a direction substantially, predominantly, and/or primarily orthogonal to the surface of the piezoelectric layer 110, which is also primarily normal, or transverse, to the direction of the electric field created by the IDT fingers.

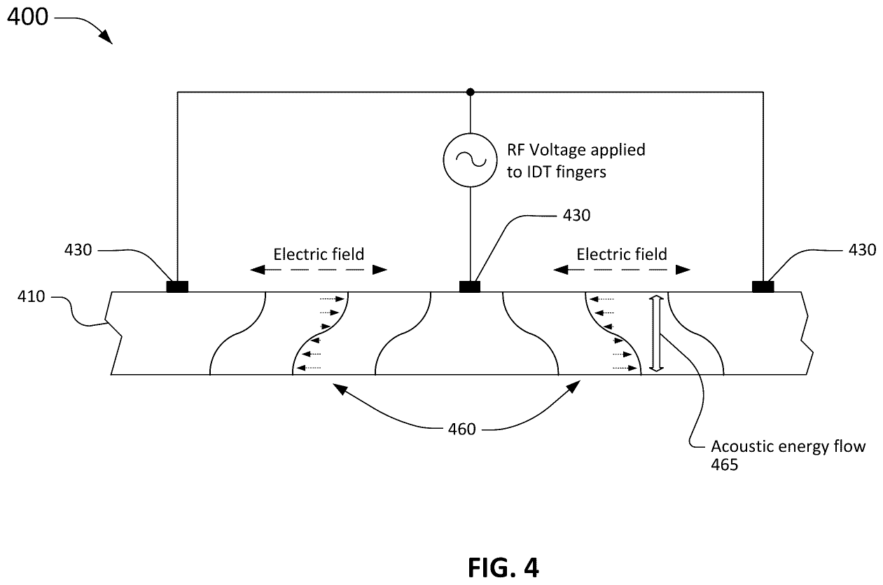

That is, when a radio frequency or a microwave signal is applied between the two busbars 132, 134, the RF voltage applied to the respective sets of IDT fingers generates a time-varying electric field that is laterally excited with respect to a surface of the piezoelectric layer 110. Thus, in some cases the primarily excited acoustic mode may be commonly referred to as a laterally excited bulk acoustic wave since displacement, as opposed to propagation, occurs primarily in the direction of the bulk of the piezoelectric layer, as discussed in more detail below in reference to FIG. 4

For purposes of this disclosure, “primarily acoustic mode” may generally refer to an operational mode in which a vibration displacement is caused in the primarily thickness-shear direction (e.g., X-direction), so the wave propagates substantially and/or primarily in the direction connecting the opposing front and back surfaces of the piezoelectric layer, that is, in the Z direction. In other words, the X-direction component of the wave is significantly smaller than the Z-direction component. The use of the term “primarily” in the “primarily excited acoustic mode” is not necessarily referring to a lower or higher order mode. Thus, the XBAR is considered a transversely excited film bulk wave resonator. One physical constraint is that when the radio frequency or microwave signal is applied between the two busbars 132, 134 of the IDT 130, heat is generated that must be dissipated from the resonator for improved performance. In general, heat can be dissipated by lateral conduction on the membrane (e.g., in the electrodes themselves), and vertical conduction through a cavity to substrate.

In any event, the IDT 130 is positioned at or on the piezoelectric layer 110 such that at least the fingers of the IDT extend at or on the portion of the piezoelectric layer 110 that is over the cavity 140, for example, the diaphragm 115 as described herein. As shown in FIG. 1A, the cavity 140 has a rectangular cross section with an extent greater than the aperture AP and length L of the IDT 130. According to other exemplary aspects, the cavity of an XBAR may have a different cross-sectional shape, such as a regular or irregular polygon. The cavity of an XBAR may have more or fewer than four sides, which may be straight or curved.

According to an exemplary aspect, the area of XBAR 100 is determined as the area of the IDT 130. For example, the area of the IDT 130 can be determined based on the measurement of the length L multiplied by the width of the aperture AP of the interleaved fingers of the IDT 130. As used herein through the disclosure, area is referenced in μm². Thus, the area of the XBAR 100 may be adjusted based on design choices, as described below, thereby adjusting the overall capacitance of the XBAR 100.

For ease of presentation in FIG. 1A, the geometric pitch and width of the IDT fingers is greatly exaggerated with respect to the length (dimension L) and aperture (dimension AP) of the XBAR. A typical XBAR has more than ten parallel fingers in the IDT. For example, an XBAR may have hundreds, possibly thousands, of parallel fingers in the IDT according to exemplary aspects. Similarly, the thickness of the fingers in the cross-sectional views is greatly exaggerated.

FIG. 1B shows a schematic cross-sectional view of an alternative XBAR configuration 100′. In FIG. 1B, the cavity 140 (which can correspond generally to cavity 140 of FIG. 1A) of the resonator 100′ is formed entirely within a dielectric layer 124 (for example silicon oxide or silicon dioxide, as in FIG. 1B) that is located between the substrate 120 (indicated as Si in FIG. 1B) and the piezoelectric layer 110 (indicated as LN in FIG. 1B). Although a single dielectric layer 124 is shown having cavity 140 formed therein (e.g., by etching), it should be appreciated that the dielectric layer 124 can be formed by a plurality of separate dielectric layers formed on each other to provide a stack of materials.

Moreover, in the example of FIG. 1B, the cavity 140 is defined on all sides by the dielectric layer 124. However, in other exemplary embodiments, one or more sides of the cavity 140 may be defined by the substrate 120 and/or the piezoelectric layer 110. In the example of FIG. 1B, the cavity 140 has a trapezoidal shape. However, as noted above, cavity shape is not limited and may be rectangular, oval, or other shapes.

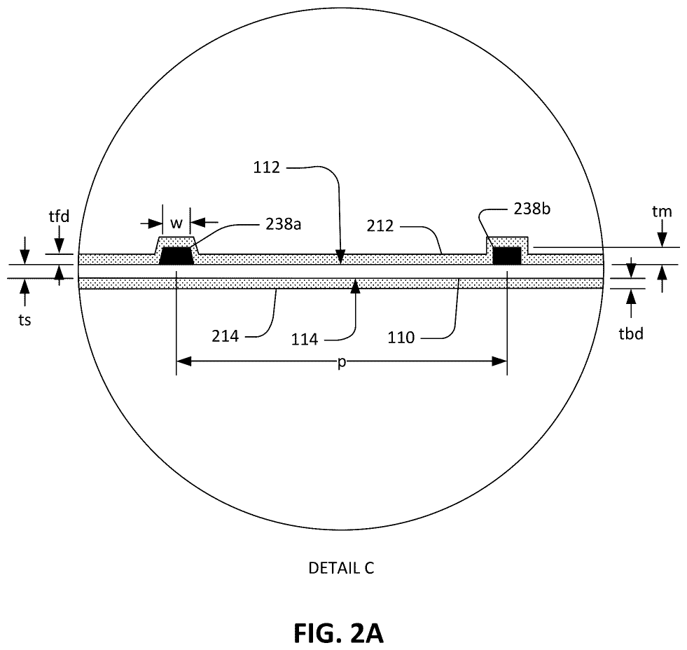

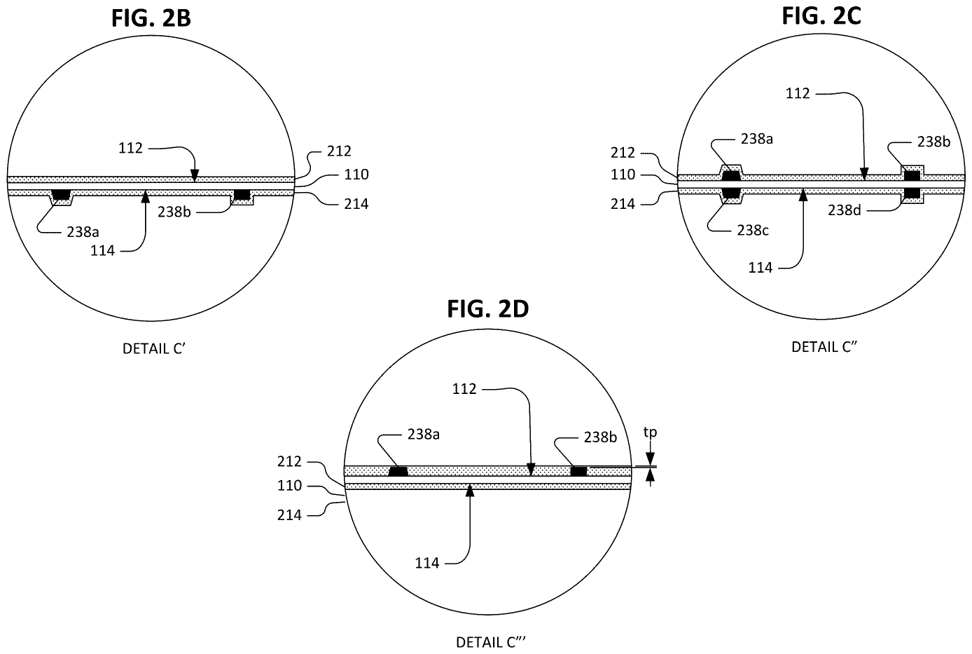

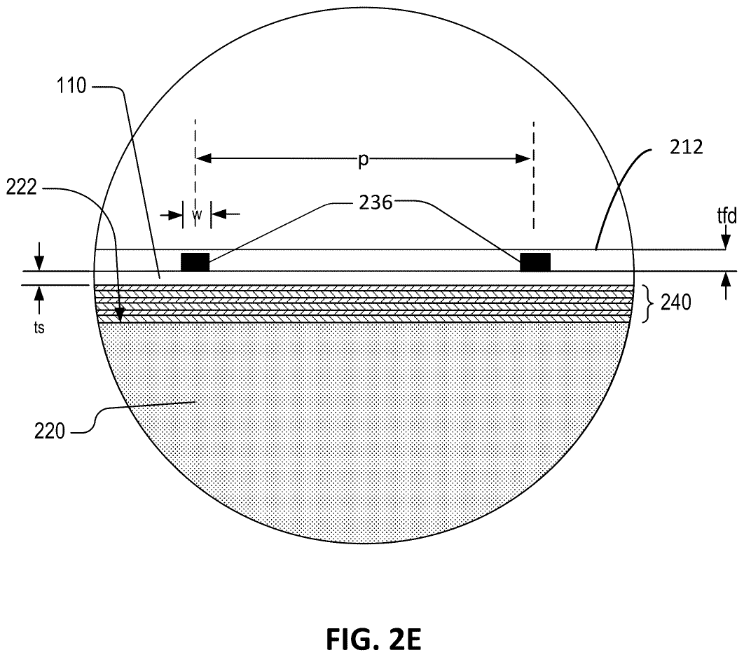

FIG. 2A shows a detailed schematic cross-sectional view (labeled as Detail C) of the XBAR 100 of FIG. 1A or 1B. The piezoelectric layer 110 is a single-crystal layer of piezoelectrical material having a thickness ts. Ts may be, for example, 100 nm to 1500 nm. When used in filters for 5G NR and Wi-Fi™ bands from 3.4 GHZ to 7 GHZ, the thickness ts may be, for example, 150 nm to 500 nm. The thickness ts can be measured in a direction substantially perpendicular or orthogonal to a surface of the piezoelectric layer in an exemplary aspect.

In this aspect, a front side dielectric layer 212 (e.g., a first dielectric coating layer or material) can be formed on the front side 112 of the piezoelectric layer 110. The “front side” of the XBAR is, by definition, the surface facing away from the substrate. The front side dielectric layer 212 has a thickness tfd. As shown in FIG. 2A the front side dielectric layer 212 covers the IDT fingers 238a, 238b, which can correspond to fingers 136 as described above with respect to FIG. 1A. Although not shown in FIG. 2A, the front side dielectric layer 212 may also be deposited only between the IDT fingers 238a, 238b. In this case, an additional thin dielectric layer (not shown) may be deposited over the IDT fingers to seal and passivate the fingers. Further, although also not shown in FIG. 2A, the front side dielectric layer 212 may also be deposited only on select IDT fingers 238a, for example.

A back side dielectric layer 214 (e.g., a second dielectric coating layer or material) can also be formed on the back side of the back side 114 of the piezoelectric layer 110. In general, for purposes of this disclosure, the term “back side” means on a side opposite the conductor pattern of the IDT structure and/or opposite the front side dielectric layer 212. Moreover, the back side dielectric layer 214 has a thickness tbd. The front side and back side dielectric layers 212, 214 may be a non-piezoelectric dielectric material, such as silicon oxide, silicon dioxide or silicon nitride. Tfd and tbd may be, for example, 0 to 500 nm. Tfd and tbd may be less than the thickness ts of the piezoelectric layer. Tfd and tbd are not necessarily equal, and the front side and back side dielectric layers 212, 214 are not necessarily the same material. In exemplary aspects, either or both of the front side and back side dielectric layers 212, 214 may be formed of multiple layers of two or more materials according to various exemplary aspects.

The IDT fingers 238a, 238b may comprise aluminum, substantially (i.e., predominantly) aluminum alloys, copper, substantially (i.e., predominantly) copper alloys, beryllium, gold, or some other conductive material. Thin (relative to the total thickness of the conductors) layers of other metals, such as chromium or titanium, may be formed under and/or over the fingers to improve adhesion between the fingers and the piezoelectric layer 110 and/or to passivate or encapsulate the fingers. The busbars (132, 134 in FIG. 1A) of the IDT may be made of the same or different materials as the fingers. The cross-sectional shape of the IDT fingers may be trapezoidal (finger 238a), rectangular (finger 238b) or some other shape in various exemplary aspects. In general, it is noted that the terms “comprise”, “have”, “include” and “contain” (and their variants) as used herein are open-ended linking verbs and allow the addition of other elements when used in a claim. Moreover, the use of the word “a” or “an” when used in conjunction with the term “comprising” in the claims or the specification means one or more than one, unless the context dictates otherwise.

Dimension p(i.e., the “pitch”) can be considered the center-to-center spacing between adjacent IDT fingers extending from different busbars, such as the IDT fingers 238a, 238b in FIGS. 2A-2D. Center points of center-to-center spacing may be measured at a center of the width “w” of a finger as shown in FIG. 2A. In some cases, the center-to-center spacing may change if the width of a given finger changes along the length of the finger, if the width and extending direction changes, or any variation thereof. In that case, for a given location along AP, center-to-center spacing may be measured as an average center-to-center spacing, a maximum center-to-center spacing, a minimum center-to-center spacing, or any variation thereof. Adjacent fingers may each extend from a different busbar and center-to-center spacing may be measured from a center of a first finger extending from a first busbar to a center of a second finger, adjacent to the first finger, extending from a second busbar. The center-to-center spacing may be constant over the length of the IDT, in which case the dimension p may be referred to as the pitch of the IDT and/or the pitch of the XBAR. However, in an alternative exemplary aspect, the center-to-center spacing varies along the length of the IDT, in which case the pitch of the IDT may be the average value of dimension p over the length of the IDT. Center-to-center spacing from one finger to an adjacent finger may vary continuously when compared to other adjacent fingers, in discrete sections of multiple adjacent pairs, or any combination thereof. Each IDT finger, such as the IDT fingers 238a, 238b in FIGS. 2A to 2D, has a width w measured normal to the long direction of each finger. The width w may also be referred to herein as the “mark.” In general, the width of the IDT fingers may be constant over the length of the IDT, in which case the dimension w may be the width of each IDT finger. However, in another exemplary aspect as will be discussed below, the width of individual IDT fingers varies along the length of the IDT 130, in which case dimension w may be the average value of the widths of the IDT fingers over the length of the IDT. Note that the pitch p and the width w of the IDT fingers are measured in a direction substantially parallel to the length L of the IDT, as defined in FIG. 1A.

In general, the IDT of an XBAR differs substantially from the IDTs used in surface acoustic wave (SAW) resonators, primarily in that IDTs of an XBAR excite a primary shear acoustic mode (also referred to as a primary shear mode, a primary shear thickness mode, or the like), as described in more detail below with respect to FIG. 4, where SAW resonators excite a surface wave in operation. Moreover, in a SAW resonator, the pitch of the IDT is one-half of the acoustic wavelength at the resonance frequency. Additionally, the mark-to-pitch ratio of a SAW resonator IDT is typically close to 0.5 (i.e., the mark or finger width is about one-fourth of the acoustic wavelength at resonance). In an XBAR, the pitch p of the IDT is typically 2 to 20 times the width w of the fingers. in addition, the pitch p of the IDT is typically 2 to 20 times the thickness ts of the piezoelectric layer 110. Moreover, the width of the IDT fingers in an XBAR is not constrained to one-fourth of the acoustic wavelength at resonance. For example, the width of XBAR IDT fingers may be 500 nm or greater, such that the IDT can be fabricated using optical lithography. The thickness tm of the IDT fingers may be from 100 nm to about equal to the width w, as the lithography process typically cannot support a configuration where the thickness is greater than the width. The thickness of the busbars (132, 134 in FIG. 1A) of the IDT may be the same as, less than, greater than, or any combination thereof, the thickness tm of the IDT fingers. It is noted that the XBAR devices described herein are not limited to the ranges of dimensions described herein.

Moreover, unlike a SAW filter, the resonance frequency of an XBAR is dependent on the total thickness of its diaphragm (i.e., in the vertical or thickness direction), including the piezoelectric layer 110, and the front side and back side dielectric layers 212, 214 disposed thereon. In an exemplary aspect, the thickness of one or both dielectric layers (i.e., on the opposing surfaces of the piezoelectric layer) can be varied to change the resonance frequencies of various XBARs in a filter. For example, shunt resonators in a ladder filter circuit may incorporate thicker dielectric layers to reduce the resonance frequencies of the shunt resonators relative to series resonators with thinner dielectric layers, and thus a thinner overall thickness.

Referring back to FIG. 2A, the thickness tfd of the front side dielectric layer 212 over the IDT fingers 238a, 238b may be greater than or equal to a minimum thickness required to cover and passivate the IDT fingers and other conductors on the front side 112 to the piezoelectric layer 110. The minimum thickness may be, for example, 10 nm to 50 nm depending on the material of the front side dielectric layer and method of deposition according to an exemplary aspect. The thickness of the back side dielectric layer 214 may be configured to a specific thickness to adjust the resonance frequency of the resonator as will be described in more detail below.

Although FIG. 2A discloses a configuration in which IDT fingers 238a and 238b are at the front side 112 of the piezoelectric layer 110, alternative configurations can be provided. For example, FIG. 2B shows an alternative configuration (identified as Detail C′) in which the IDT fingers 238a, 238b are at the back side 114 of the piezoelectric layer 110 (i.e., facing the cavity) and are covered by a back side dielectric layer 214. A front side dielectric layer 212 may cover the front side 112 of the piezoelectric layer 110. In exemplary aspects, a dielectric layer disposed on the diaphragm of each resonator can be trimmed or etched to adjust the resonant frequency. However, if the dielectric layer is on the side of the diaphragm facing the cavity, there may be a change in spurious modes (e.g., generated by the coating on the fingers). Moreover, with the passivation layer coated on top of the IDTs, the mark changes, which can also cause spurs. Therefore, disposing the IDT fingers 238a, 238b at the back side 114 of the piezoelectric layer 110 as shown in FIG. 2B may eliminate addressing both the change in frequency as well as the effect it has on spurs as compared when the IDT fingers 238a and 238b are on the front side 112 of the piezoelectric layer 110.

FIG. 2C shows an alternative configuration (identified as Detail C″) in which IDT fingers 238a, 238b are on the front side 112 of the piezoelectric layer 110 and are covered by a front side dielectric layer 212. IDT fingers 238c, 238d are also on the back side 114 of the piezoelectric layer 110 and are also covered by a back side dielectric layer 214. As previously described, the front side and back side dielectric layer 212, 214 are not necessarily the same thickness or the same material.

FIG. 2D shows another alternative configuration (identified as Detail C″) in which IDT fingers 238a, 238b are on the front side 112 of the piezoelectric layer 110 and are covered by a front side dielectric layer 212. The surface of the front side dielectric layer is planarized. The front side dielectric layer may be planarized, for example, by polishing or some other method. A thin layer of dielectric material having a thickness tp may cover the IDT finger 238a, 238b to seal and passivate the fingers. The dimension TP may be, for example, 10 nm to 50 nm.

Each of the XBAR configurations described above with respect to FIGS. 2A to 2D include a diaphragm spanning over a cavity. However, in an alternative aspect, the bulk acoustic resonator can be solidly mounted in which the diaphragm with IDT fingers is mounted on or above a Bragg mirror, which in turn can be mounted on a substrate.

In particular, FIG. 2E shows a detailed schematic cross-sectional view of a solidly mounted XBAR (SM-XBAR). It is noted that FIG. 2E generally discloses a similar cross section as that of FIG. 1A, except having a solidly mounted configuration. In this aspect, the SM-XBAR includes a piezoelectric layer 110 and an IDT (of which only two fingers 236 are visible) with a dielectric layer 212 disposed on the piezoelectric layer 110 and IDT fingers 236. The piezoelectric layer 110 has parallel front and back surfaces similar to the configurations described above. Dimension ts is the thickness of the piezoelectric layer 110. The width of the IDT fingers 236 is dimension w, thickness of the IDT fingers is dimension tm, and the IDT pitch is dimension p.

In contrast to the XBAR devices shown in FIG. 1A, the IDT of an SM XBAR in FIG. 2E is not formed on a diaphragm spanning a cavity in the substrate. Instead, an acoustic Bragg reflector 240 is sandwiched between a surface 222 of the substrate 220 and the back surface of the piezoelectric layer 110. The term “sandwiched” means the acoustic Bragg reflector 240 is both disposed between and mechanically attached to a surface 222 of the substrate 220 and the back surface of the piezoelectric layer 110. In some circumstances, layers of additional materials (e.g., one or more dielectric layers) may be disposed between the acoustic Bragg reflector 240 and the surface 222 of the substrate 220 and/or between the Bragg reflector 240 and the back surface of the piezoelectric layer 110. Such additional material layers may be present, for example, to facilitate bonding the piezoelectric layer 110, the acoustic Bragg reflector 240, and the substrate 220.

The acoustic Bragg reflector 240 may be an acoustic mirror configured to reflect at least a portion of the primary acoustic mode excited in the piezoelectric and includes multiple dielectric layers that alternate between materials having high acoustic impedance and materials having low acoustic impedance. The acoustic impedance of a material is the product of the material's shear wave velocity and density. “High” and “low” are relative terms. For each layer, the standard for comparison is the adjacent layers. Each “high” acoustic impedance layer has an acoustic impedance higher than that of both the adjacent low acoustic impedance layers. Each “low” acoustic impedance layer has an acoustic impedance lower than that of both the adjacent high acoustic impedance layers. As discussed above, the primary acoustic mode in the piezoelectric layer of an XBAR is a shear bulk wave. In an exemplary aspect, each layer of the acoustic Bragg reflector 240 has a thickness equal to, or about, one-fourth of the wavelength in the layer of a shear bulk wave having the same polarization as the primary acoustic mode at or near a resonance frequency of the SM XBAR. Dielectric materials having comparatively low acoustic impedance include silicon dioxide, carbon-containing silicon oxide, and certain plastics such as cross-linked polyphenylene polymers. Materials having comparatively high acoustic impedance include hafnium oxide, silicon nitride, aluminum nitride, silicon carbide. All of the high acoustic impedance layers of the acoustic Bragg reflector 240 are not necessarily the same material, and all of the low acoustic impedance layers are not necessarily the same material. In the example of FIG. 2E, the acoustic Bragg reflector 240 has a total of six layers, but an acoustic Bragg reflector may have more than, or less than, six layers in alternative configurations.

The IDT fingers, such as IDT finger 236, 238a, and 238b, may be disposed on a surface of the front side 112 of the piezoelectric layer 110. Alternatively, IDT fingers, such as IDT finger 236, 238a, and 238b, may be disposed in grooves formed in the surface of the front side 112. The grooves may extend partially through the piezoelectric layer. Alternatively, the grooves may extend completely through the piezoelectric layer.

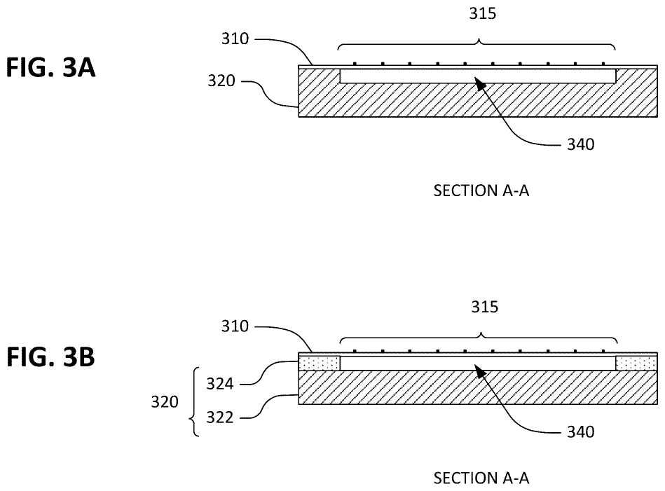

FIG. 3A and FIG. 3B show two exemplary cross-sectional views along the section plane A-A defined in FIG. 1A of XBAR 100. In FIG. 3A, a piezoelectric layer 310, which corresponds to piezoelectric layer 110, is attached directly to a substrate 320, which can correspond to substrate 120 of FIG. 1A. Moreover, a cavity 340, which does not fully penetrate the substrate 320, is formed in the substrate under the portion (i.e., the diaphragm 315) of the piezoelectric layer 310 containing the IDT of an XBAR. The cavity 340 can correspond to cavity 140 of FIGS. 1A and/or 1B in an exemplary aspect. In an exemplary aspect, the cavity 340 may be formed, for example, by etching the substrate 320 before attaching the piezoelectric layer 310. Alternatively, the cavity 340 may be formed by etching the substrate 320 with a selective etchant that reaches the substrate through one or more openings provided in the piezoelectric layer 310.

FIG. 3B illustrates an alternative aspect in which the substrate 320 includes a base 322 and an intermediate layer 324 that is disposed between the piezoelectric layer 310 and the base 322. For example, the base 322 may be silicon (e.g., a silicon support substrate) and the intermediate layer 324 may be silicon dioxide or silicon nitride or some other material, e.g., an intermediate dielectric layer. That is, in this aspect, the base 322 and the intermediate layer 324 are collectively considered the substrate 320. As further shown, cavity 340 is formed in the intermediate layer 324 under the portion (i.e., the diaphragm 315) of the piezoelectric layer 310 containing the IDT fingers of an XBAR. The cavity 340 may be formed, for example, by etching the intermediate layer 324 before attaching the piezoelectric layer 310. Alternatively, the cavity 340 may be formed by etching the intermediate layer 324. In other example embodiments, the cavity 340 may be defined in the intermediate layer 324 by other means from whether the intermediate layer 324 was etched to define the cavity 340. In some cases, the etching may be performed with a selective etchant that reaches the substrate through one or more openings (not shown) provided in the piezoelectric layer 310.

In this case, the diaphragm 315, which can correspond to diaphragm 115 of FIG. 1A, for example, in an exemplary aspect, may be contiguous with the rest of the piezoelectric layer 310 around a large portion of a perimeter of the cavity 340. For example, the diaphragm 315 may be contiguous with the rest of the piezoelectric layer 310 around at least 50% of the perimeter of the cavity 340. As shown in FIG. 3B, the cavity 340 extends completely through the intermediate layer 324. That is, the diaphragm 315 can have an outer edge that faces the piezoelectric layer 310 with at least 50% of the edge surface of the diaphragm 315 coupled to the edge of the piezoelectric layer 310 facing the diaphragm 315. This configuration provides for increased mechanical stability of the resonator.

In other configurations, the cavity 340 may partially extend into, but not entirely through the intermediate layer 324 (i.e., the intermediate layer 324 may extend over the bottom of the cavity on top of the base 322) or may extend through the intermediate layer 324 and into (either partially or wholly) the base 322. As described above, it should be appreciated that the interleaved fingers of the IDT can be disposed on either or both surfaces of the diaphragm 315 in FIGS. 3A and 3B according to various exemplary aspects.

FIG. 4 is a graphical illustration of the primarily excited acoustic mode of interest in an XBAR. FIG. 4 shows a small portion of an XBAR 400 including a piezoelectric layer 410 and three interleaved IDT fingers 430. In general, the exemplary configuration of XBAR 400 can correspond to any of the configurations described above and shown in FIGS. 2A to 2D according to an exemplary aspect. Thus, it should be appreciated that piezoelectric layer 410 can correspond to piezoelectric layer 110 and IDT fingers 430 can be implemented according to any of the configurations of fingers 238a and 238b, for example.

In operation, an RF voltage is applied to the interleaved fingers 430. This voltage creates a time-varying electric field between the fingers. The direction of the electric field is lateral (i.e., laterally excited), or primarily parallel to the surface of the piezoelectric layer 410, as indicated by the arrows labeled “electric field.” Due to the high dielectric constant of the piezoelectric layer 410, the electric field is highly concentrated in the piezoelectric layer relative to the air. The lateral electric field introduces shear deformation in the piezoelectric layer 410, and thus strongly excites a shear acoustic mode, in the piezoelectric layer 410. In this context, “shear deformation” is defined as deformation in which parallel planes in a material remain parallel and maintain a constant distance while translating relative to each other. In other words, the parallel planes of material are laterally displaced with respect to each other. A “shear acoustic mode” is defined as an acoustic vibration mode in a medium that results in shear deformation of the medium.

The shear deformations in the XBAR 400 are represented by the curves 460, with the adjacent small arrows providing a schematic indication of the direction and magnitude of atomic motion. It is noted that the degree of atomic motion, as well as the thickness of the piezoelectric layer 410, have been exaggerated for ease of visualization in FIG. 4. While the atomic motions are predominantly lateral (i.e., horizontal as shown in FIG. 4), the direction of acoustic energy flow of the primarily excited shear acoustic mode is substantially and/or primarily orthogonal to the surface of the piezoelectric layer, as indicated by the arrow 465.

A bulk acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. In such devices, the acoustic mode is compressive with atomic motions and the direction of acoustic energy flow in the thickness direction. In addition, the piezoelectric coupling for shear wave XBAR resonances can be high (>20%) compared to other acoustic resonators. Thus, high piezoelectric coupling enables the design and implementation of microwave and millimeter-wave filters with appreciable bandwidth.

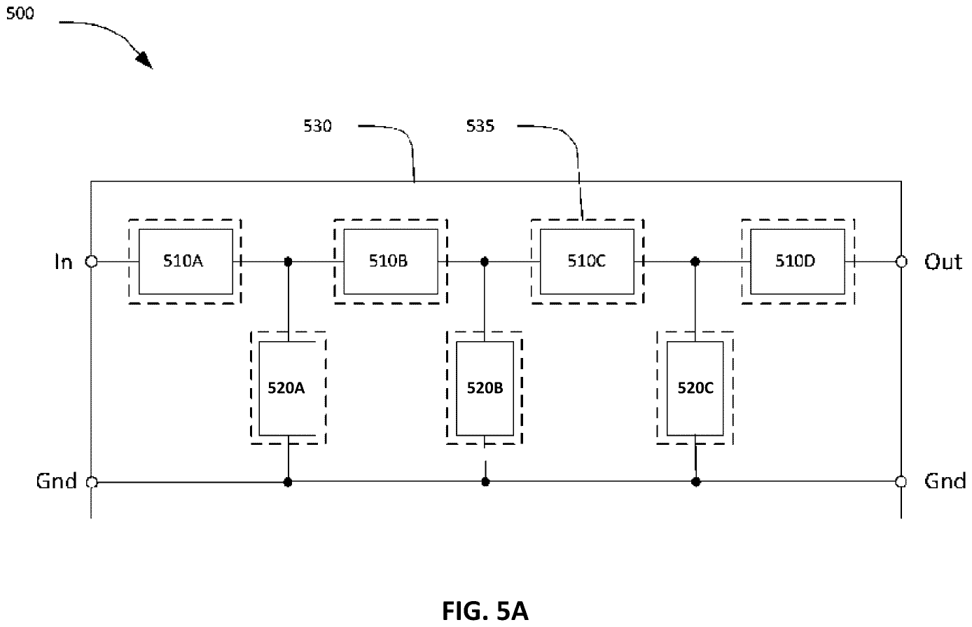

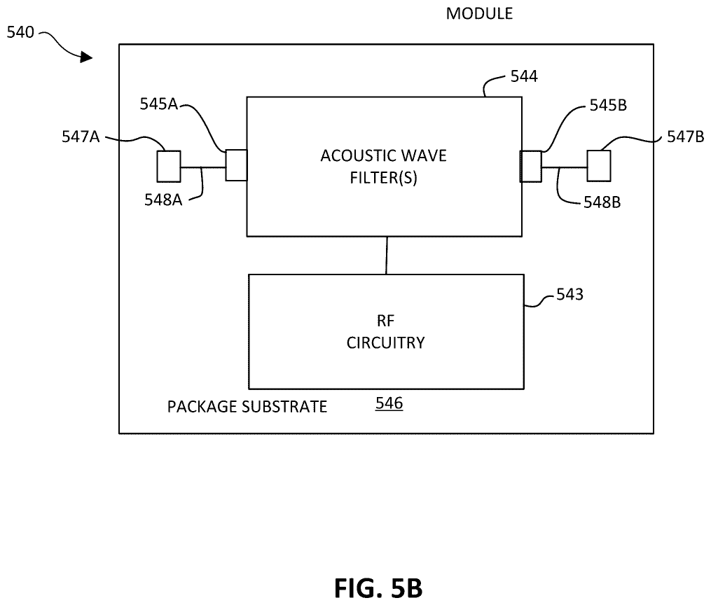

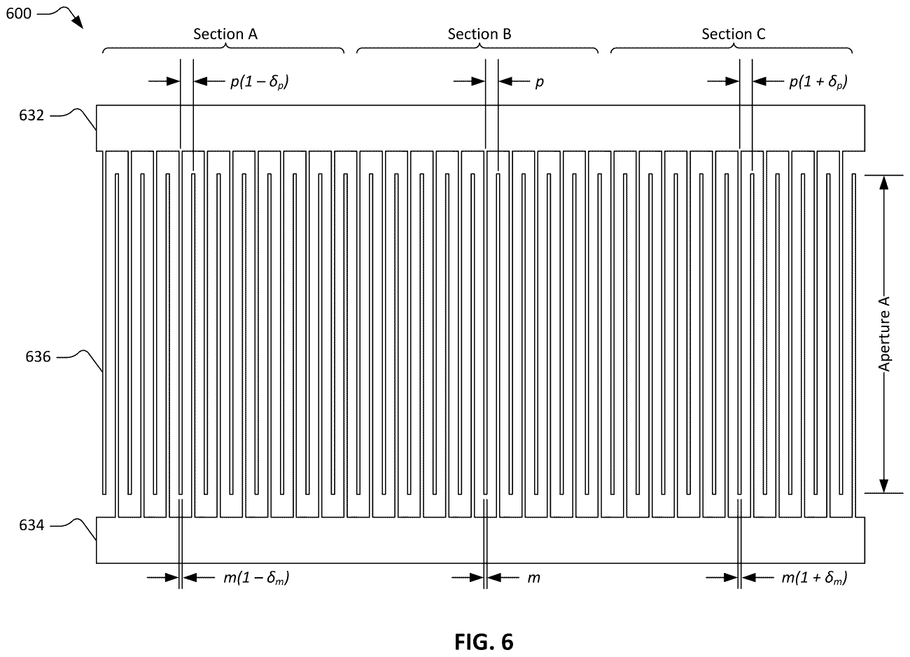

FIG. 5A is a schematic circuit diagram and layout for a high frequency bandpass filter 500 using XBARs, such as the general XBAR configuration 100 (e.g., the bulk acoustic resonators) described above, for example. The filter 500 has a conventional ladder filter architecture, which may include a split-ladder filter architecture wherein the filter is split between multiple chips, that has a plurality of bulk acoustic resonators including four resonators 510A, 510B, 510C, and 510D and three shunt resonators 520A, 520B and 520C. The series resonators 510A, 510B, 510C and 510D are connected in series between a first port and a second port (hence the term “series resonator”). In FIG. 5A, the first and second ports are labeled “In” and “Out”, respectively. However, the filter 500 is bidirectional and either port may serve as the input or output of the filter. At least two shunt resonators, such as the shunt resonators 520A and 520B, are connected from nodes between series resonators to a ground connection. A filter may contain additional reactive components, such as inductors, not shown in FIG. 5A. All the shunt resonators and series resonators are XBARs (e.g., either of the XBAR configurations 100 and/or 100′ as discussed above) in the exemplary aspect. The inclusion of three series and two shunt resonators is an example. A filter may have more or fewer than five total resonators, more or fewer than three series resonators, and more or fewer than two shunt resonators. Typically, for a split ladder and non-split-ladder filter architectures, all of the series resonators are connected in series between an input and an output of the filter, and all of the shunt resonators are typically connected between ground and the input, the output, or a node between two series resonators.

In the exemplary filter 500, the series resonators 510A, 510B, 510C and 510D and the shunt resonators 520A, 520B and 520C of the filter 500 can be formed on at least one, and in some cases a single, piezoelectric layer 530 of piezoelectric material bonded to a silicon substrate (not visible). However, in alternative aspects, the individual resonators may each be formed on a separate respective piezoelectric layer for each resonator wherein all resonators are located on the same chip. In some cases, however different resonators of a filter may be bonded to a separate substrate, for example. This may result in a split-ladder architecture that can include one or a plurality of separate chips that include separate piezoelectric layers and IDTs of one or more bulk acoustic resonators that are then configured together to form the overall split ladder filter. Moreover, each resonator includes a respective IDT (not shown), with at least the fingers of the IDT disposed over a cavity, or an acoustic mirror, in the substrate. In this and similar contexts, the term “respective” means “relating things each to each,” which is to say with a one-to-one correspondence. In FIG. 5A, the cavities are illustrated schematically as the dashed rectangles (such as the rectangle 535). In this example, each IDT is disposed over a respective cavity. In other filters, the IDTs of two or more resonators may be disposed over a single cavity.

Each of the resonators 510A, 510B, 510C, 510D, 520A, 520B and 520C in the filter 500 has a resonance where the admittance (also interchangeably referred to as Y-parameter) of the resonator is very high and an anti-resonance where the admittance of the resonator is very low. The resonance and anti-resonance occur at a resonance frequency and an anti-resonance frequency, respectively, which may be the same or different for the various resonators in the filter 500. In simplified terms, each resonator can be considered a short-circuit at its resonance frequency and an open circuit at its anti-resonance frequency. The input-output transfer function will be near zero at the resonance frequencies of the shunt resonators and at the anti-resonance frequencies of the series resonators. In a typical filter, the resonance frequencies of the shunt resonators are positioned below the lower edge of the filter's passband and the anti-resonance frequencies of the series resonators are positioned above the upper edge of the passband.

The frequency range between resonance and anti-resonance frequencies of a resonator corresponds to the coupling of the resonator. Depending on the design parameters of the filter 500, each of the resonators 510A, 510B, 510C, 510D, 520A, 520B and 520C may have a particular coupling parameter to which the respective resonator is tuned in order to achieve the required frequency response of the filter 500.

According to an exemplary aspect, each of the series resonators 510A, 510B, 510C and 510D and the shunt resonators 520A, 520B and 520C can have an XBAR configuration as described above with respect to FIGS. 1A-2D in which a diaphragm with IDT fingers spans over a cavity. Alternatively, each of the series resonators 510A, 510B, 510C, 510D and the shunt resonators 520A, 520B, and 520C can have an XBAR configuration in which the series resonators 510A, 510B, 510C, 510D and/or the shunt resonators 520A, 520B, and 520C can be solidly mounted on or above a Bragg mirror (e.g., as shown in FIG. 2E), which in turn can be mounted on a substrate.

FIG. 5B is a schematic diagram of a radio frequency module that includes an acoustic wave filter device according to an exemplary aspect. In particular, FIG. 5B illustrate a radio frequency module 540 that includes one or more acoustic wave filters 544 according to an exemplary aspect. The illustrated radio frequency module 540 also includes radio frequency (RF) circuitry (or RF circuit) 543. In an exemplary aspect, the acoustic wave filters 544 may include one or more of filter 500 including XBARs (e.g., the bulk acoustic resonators described herein), as described above with respect to FIG. 5A.

The acoustic wave filter 544 shown in FIG. 5B includes terminals 545A and 545B (e.g., first and second terminals). The terminals 545A and 545B can serve, for example, as an input contact and an output contact for the acoustic wave filter 544. Although two terminals are illustrated, any suitable number of terminals can be implemented for a particular application. The acoustic wave filter 544 and the RF circuitry 543 are on a package substrate 546 (e.g., a common substrate) in FIG. 5B. The package substrate 546 can be a laminate substrate. The terminals 545A and 545B can be electrically connected to contacts 547A and 547B, respectively, on the package substrate 546 by way of electrical connectors 548A and 548B, respectively. The electrical connectors 548A and 548B can be bumps or wire bonds, for example. In an exemplary aspect, the acoustic wave filter 544 and the RF circuitry 543 may be enclosed together within a common package, with or without using the package substrate 546.

The RF circuitry 543 can include any suitable RF circuitry. For example, the RF circuitry can include one or more radio frequency amplifiers (e.g., one or more power amplifiers and/or one or more low noise amplifiers), one or more radio frequency switches, one or more additional RF filters, one or more RF couplers, one or more delay lines, one or more phase shifters, or any suitable combination thereof. The RF circuitry 543 can be electrically connected to the one or more acoustic wave filters 544. The radio frequency module 540 can include one or more packaging structures to, for example, provide protection and/or facilitate easier handling of the radio frequency module 540. Such a packaging structure can include an overmold structure formed over the package substrate 546. The overmold structure can encapsulate some or all of the components of the radio frequency module 540.

As described above, the pitch p is the center-to-center spacing between adjacent IDT fingers extending from different busbars. Moreover, the mark is the width of a given finger of the IDT. That is, each finger of the IDT has a mark (e.g., the width w in FIG. 2A) that can typically be measured in the same direction as the pitch, which may typically be orthogonal to direction in which the interleaved fingers extend from the respective busbars. The exemplary aspect shown in FIG. 1A can, for example, be considered to have a substantially constant pitch and mark across the length L of the IDT 130.

However, since the primary acoustic mode of an XBAR is mostly bulk in nature, this configuration can result in weak frequency dependence on mark and pitch. Thus, chirping (or variance) of the pitch, the mark, or both, in the IDT of an XBAR can suppress undesirable spurious magnitudes for small signal or large signal performance gains that otherwise depend upon pitch and/or mark, such as metal and propagating modes, with only slight broadening of the primary mode resonance. It is noted that in general, IDT chirp is defined by the variation of pitch (e.g., a multi-pitch) or the variation of the mark (e.g., a multi-mark) along the length of the device.

FIG. 6 is a plan view of a multi-mark multi-pitch IDT 600 according to an exemplary aspect. A “multi-mark IDT” is an IDT where the mark of the IDT fingers varies along the length of the IDT. Similarly, a “multi-pitch IDT” is an IDT where the pitch of the IDT fingers varies along the length of the IDT. As shown, the multi-mark IDT 600 includes a first busbar 632, and a second busbar 634, and a plurality of interleaved fingers 636 that alternately extend from the first busbar 632 and the second busbar 634. In general, it should be understood that the busbars 632 and 634 can correspond to busbars 132 and 134 of FIG. 1A as described above. Moreover, interleaved fingers 636 can correspond to fingers 136 of IDT 130, for example. The main difference is that IDT 600 has a configuration of the interleaved fingers 636 that is multi-mark and multi-pitch.

As further shown, the multi-mark IDT 600 is divided into three sections, identified as Section A, Section B, and Section C, along the length L of the IDT 600. In an exemplary aspect, Section A, Section B, and Section C can generally be considered a first section, a second section and a third section, respectively, with the second section being a center section that is between the first and third sections in a length direction of the IDT. In another exemplary aspect, Section A, Section B, and Section C can generally be considered a first section, a last section and a center section disposed between the first and last sections in the length direction of the IDT. In either case, it should be appreciated that the IDT 600 can include more than three separate sections in alternative aspects.

In an exemplary aspect, each of Sections A, B, and C includes 20 fingers, for a total of 60 fingers in the multi-mark IDT 600. The use of three sections and 60 fingers is exemplary. An IDT may have more than or fewer than 60 total fingers. For example, each section of IDT 600 may have less fingers as long as each section is considered to have at least two pairs of interleaved fingers (i.e., four total fingers, or at least three total interleaved fingers wherein a second finger is counted twice-once for a first pair and once for a second pair) according to an exemplary aspect. Moreover, in an exemplary aspect, the total number of fingers may be divided essentially equally between the two or more sections, such as Sections A and B. In this context, “essentially” means “as close as possible.” For example, an IDT with 100 fingers divided into three sections with 33, 34, and 33 fingers is considered to be divided essentially equally. However, the total number of fingers may also be divided unequally between the two or more sections.

In the exemplary aspect of IDT 600, the fingers in Section B have mark m, which can be considered the nominal mark of the IDT 600. The fingers of Section A have a mark of m (1−δₘ), and the fingers of Section C have a mark of m (1+δₘ). In an exemplary aspect, om can be greater than 0 and less than or equal to 0.05. Moreover, om may typically be less than 0.01 and can be selected during a filter design to achieve the most effective reduction of spurious modes. In an exemplary aspect, when an IDT is divided into two sections or more than three sections, the maximum mark may be m (1+δₘ) and the minimum mark may be m (1−δₘ).

As further shown, the fingers in Section B have a pitch p, which can be considered the nominal pitch of the IDT 600. The finger of Section A can have a pitch of p(1−δₚ), and the fingers of Section C can have a pitch of p(1+δₚ). In this aspect, & can be greater than 0 and less than or equal to 0.10. Moreover, δₚ may typically be less than 0.01 and can be selected during a filter design to achieve the most effective reduction of spurious modes.

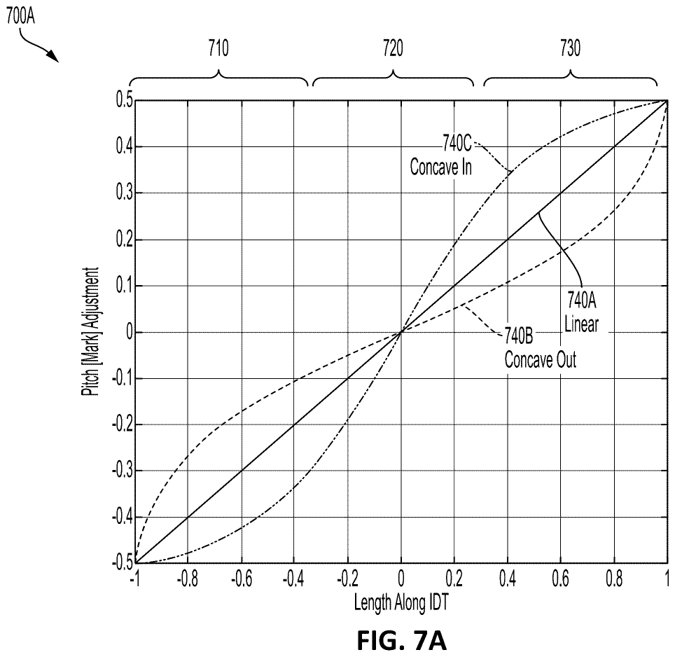

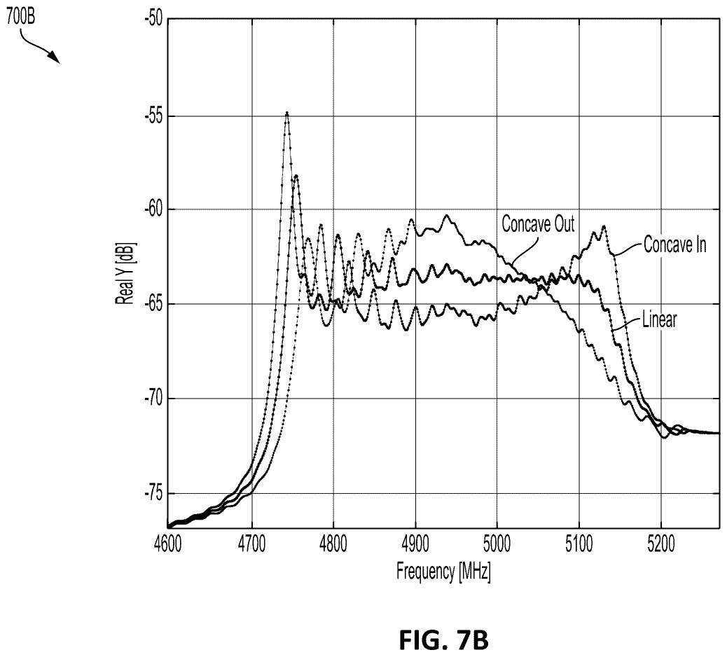

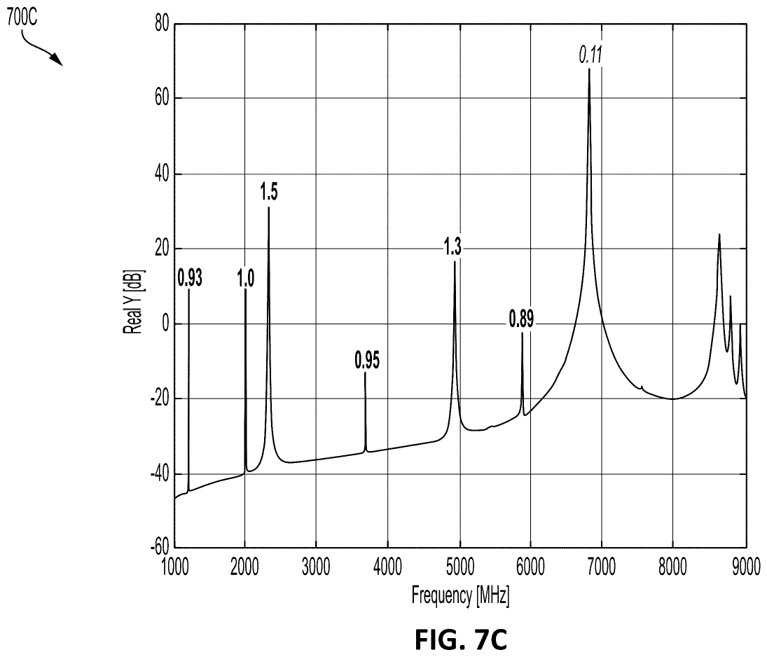

In the example multi-mark multi-pitch IDT 600, the mark and pitch can increase monotonically from left (as seen in the figure) to right. Thus, IDT 600 generally shows a chirping profile in which the chirp pattern (i.e., the increase is variation of the pitch and/or mark) is a linear variation along the length of the IDT. However, as will be discussed as follows, in an exemplary aspect of the present disclosure, the IDT and/or one or more sections of the IDT can have a chirp pattern with a nonlinear (e.g., concave in or concave out) profile. A pitch profile and/or mark profile, either together or separately, may be referred to herein as chirping profiles. For example, a pitch profile may refer to a shape of a line fit to points on a graph having pitch on one axis and positions of IDT fingers along a length of the IDT on the other axis. Similarly, a mark profile may refer to a shape of a line fit to points on a graph having mark on one axis and positions of IDT fingers along a length of an IDT on the other axis. Examples of pitch profiles may be seen in at least FIGS. 7A, 8A, 8B, and 9A. As illustrated, shapes showing the change in pitch (i.e., pitch profiles) may be seen even though sections, or subsections having at least three interleaved fingers, have the same pitch.

FIG. 7A is a graph 700A of IDT chirping profiles as a function of position along a length of multiple IDTs according to exemplary aspects. In general, the X axis represents the position along the length of the IDT, which can be denoted as “x” in an exemplary aspect. Thus, x ranges from −1 to +1, with X=0 at a center position of the IDT. The Y axis represents relative IDT chirping (either the variation in the pitch and/or the variation in the mark) for a given position along the length of the IDT.

As further shown, line 740A shows the pitch (or mark) adjustment (also referred to as the variation) as a function of position along the length of the IDT for an IDT having a linear chirping variation, as described above with respect to FIG. 6, for example, where the pitch linearly increases from p(1−δₚ) in Section A to pin Section B to p(1+δₚ) in Section C, and/or similarly, the mark linearly increases from p(1−δₘ) in Section A to m in Section B to p(1+δₘ) in Section C. In contrast, line 740B and line 740C illustrate IDTs of acoustic resonator devices that have chirp patterns with nonlinear profiles.

More particularly, line 740B shows the pitch (or mark) adjustment (i.e., the variation) as a function of position along the length of the IDT for an IDT having a “concave out” chirping profile in which the variation in the pitch and/or mark is flatter towards the center of the IDT (relative to its overall length) and steeper at the edges of the IDT that are farther away from the center of the IDT. On the other hand, line 740C shows the pitch (or mark) adjustment (i.e., the variation) as a function of position along the length of the IDT for an IDT having a “concave in” chirping profile in which the variation in the pitch and/or mark is steeper towards the center of the IDT (relative to its overall length) and flatter at the edges of the IDT that are farther away from the center of the IDT.

According to the exemplary aspect as described above, the chirping (or variance) of the pitch and/or the mark of the IDT of an XBAR suppresses undesirable spurious magnitudes for small signal or large signal performance gains. FIG. 7B illustrates a graph 700B showing the performance difference between the linear chirping profile 740A, the concave out chirping profile 740B and the concave in chirping profile 740C as described above with respect to FIG. 7B. The plots are simulated using finite element method (FEM) simulation techniques, where the X axis represents the resonant frequency (in MHz), and the Y axis represents admittance real Y in dB against the frequency.

As shown, the three chirping profiles with a same chirp magnitude are compared in graph 700B for unwanted spurious modes with the degree of suppression varying considerably between profiles. In this example, the “concave out” chirping profile demonstrates the best spurious suppression, which can be perceived by the fewest peaks in the respective frequency responses, especially at the upper and lower edges of the passband.

Thus, referring back to FIG. 7A, the IDT can generally be divided into at least two sections and, in this case, IDT in the graph 700A in FIG. 7A is shown to be divided into three sections 710, 720 and 730 in a similar way as described above with respect to FIG. 6. Thus, according to the exemplary aspect, an acoustic resonator is provided that includes a piezoelectric layer and an interdigital transducer (IDT) on a surface of the piezoelectric layer. In this aspect, the IDT can have a plurality of interleaved fingers that alternately extend from a first busbar and a second busbar. That is, the IDT can include at least three sections that includes a first section 710, a last section 730 and a center section 720 disposed between the first section 710 and the last section 730 in a length direction of the IDT. Alternatively, the three sections can be considered a first section 710, a second section 720 and a third section 730.

Although the at least three sections are visually shown to be a substantially similar length in the graph 700A, it should be appreciated that each of the first section 710, the center section 720 and the last section 730 can have a different number of fingers from each other as long as the at least three sections each comprise a respective length that includes at least two pairs of interleaved fingers in each section.

Unlike the configuration of IDT 600 described above with respect to FIG. 6, the nonlinear chirp profiles 740B and 740C of the exemplary aspect shown in FIG. 7A includes one or more sections of the IDT that has a non-linear chirping profile. Thus, according to an exemplary aspect, at least one section of the first section 710 and the last section 730 of each of the IDTs comprises a non-linear chirping profile, such that a variation of at least one of a mark and a pitch of the at least one section is non-linear across the length of the at least one section. As also described above, the mark is the width of each finger of the at least two pairs of interleaved fingers and the pitch is a center-to-center spacing between each pair of interleaved fingers. As further shown, the center section 720 has a different pitch or mark profile than the at least one section (e.g., either of the sections 710 and/or 730). As will be described in more detail below, the at least one section can be configured to have a non-linear chirping profile to effectively suppress a “hot spot” of the spurious mode.

According to an exemplary aspect, the line 740B illustrates a concave out chirping profile. In this instance, at least the first section 710 and the last section 730 of the IDT comprise a non-linear chirping profile that is concave out, such that the variation of the at least one of the mark and the pitch of each of the first section 710 and the last section 730 is flatter towards the center section 720 and steeper as the respective section extends away from the center section 720. In this aspect, the variation of the at least one of the mark and the pitch of both the first section 710 and last section 730 can be represented by A(x), where

$$A ( x ) = \frac{A}{2} a tanh ( x tanh ( 2 π k ) ) ,$$

where k>0 and x is between −1 and +1, which represents the length of the IDT. Moreover, K is a measure of the curvature of the non-linear chirping profile (e.g., the hyperbolic curve) as shown in FIG. 7A, for example. As described above with respect to FIG. 1A, in one exemplary aspect, the length of the IDT is the center-to-center distance L between the outermost fingers of the IDT.

According to another exemplary aspect, the line 740C illustrates a concave in chirping profile. In this instance, at least the first section 710 and the last section 730 of the IDT comprise a non-linear chirping profile that is concave in, such that the variation of the at least one of the mark and the pitch of each of the first section 710 and last section 730 is steeper towards the center section 720 and flatter as the respective section extends away from the center section 720. In this aspect, the variation of the at least one of the mark and the pitch of both the first section 710 and last section 730 is represented by A(x), where:

$$A ( x ) = \frac{A}{2} \frac{tanh ( 2 π kx )}{tanh ( 2 π k )} ,$$

where k>u and x is between −1 and +1, which again represents the length of the IDT. It is noted that while the line 740B illustrates a concave out IDT chirping profile and the line 740C illustrates a concave in IDT chirping profile, in an alternative aspect, the first section 710 could have a concave in chirping profile and the last section 730 could have a concave out chirping profile, or vice versa.

FIG. 7C provides a graph 700C that illustrates a ratio on an effect of chirping on different vibrational modes of an acoustic resonator. The plot is simulated using finite element method (FEM) simulation techniques, where the X axis represents the resonant frequency (in MHz), and the Y axis represents admittance real Y in dB against the frequency.

In particular, graph 700C illustrates how changes in pitch affects a main mode (e.g., a primarily excited main acoustic mode) versus other spurious modes. The value for x (discussed below) is illustrated for each spur at the different frequencies. In particular, graph 700C illustrates two spur categories for: (i) chirpable (e.g., values “0.93”, “1.0”, “1.5”, “0.95”, “1.3” and “0.89”), and (ii)) main XBAR main (e.g., value “0.11”). For purposes of this disclosure, “chirpable” generally means the effectiveness of pitch changes (i.e., pitch chirping) on unwanted spurs of the resonant frequency response.

According to the exemplary aspect, a spur's response to chirping can be evaluated based on the ratio:

$$x = \frac{{p}_{0}}{{f}_{0}} \frac{df}{dp}$$

In this aspect, po is the nominal pitch of the acoustic resonator device and f₀ the nominal spur frequency. Moreover, df is the change in frequency an dp is the change in pitch. As shown and according to the exemplary aspect, the spur category of the main XBAR mode has a χ of less than 0.25.

Moreover, for a “chirpable” spur or SAW device, χ≈1 in which the resonator device's resonant frequency is predominantly controlled by the pitch of its IDT. However, for the bulk acoustic resonators described herein according to the exemplary aspect, the primarily excited main acoustic mode has χ≈0.1, and, in this particular exemplary case, the χ value is 0.11.

Thus, in the exemplary aspect, the precise value of χ generally depends on the ratio of the IDT pitch to the thickness of the piezoelectric layer. The exemplary acoustic resonator device for the spur category of the main XBAR mode has a small pitch to piezoelectric layer thickness ratio (e.g., ~5.3) so the value of χ will be on the higher range for typical XBAR devices. However, it is noted that the upper bound of 0.25 can be decreased and the gap can be widened between chirpable and unchirpable in other exemplary aspects.

Thus, according to the exemplary aspect as shown in graph 700C of FIG. 7C, a specific unwanted frequency is more “chirpable” when the χ is closer to 1 or larger than 1, whereas the main XBAR mode has a χ of less than 0.25. Effectively, the change in pitch (or mark) has a less than 25% effect on the XBAR main mode as compared to a SAW device. In other words, the change in pitch and/or mark according to the exemplary aspects described above has a less than 25% effect on the primarily excited main acoustic mode of the acoustic resonator device as compared to a 1:1 effect of pitch and/or mark on the main mode. That is, according to the exemplary acoustic resonator devices described herein, the variation of the pitch has a less than 25% effect on a main A1 mode of the acoustic resonator in comparison to a 1:1 effect of at least one of a pitch and a mark on a mode other than the primarily excited main acoustic mode and associated frequencies. In terms of mark, while changes in mark may be useful to balance out effects of the change in pitch, the effects may not be significantly different in the main mode vs. other modes.

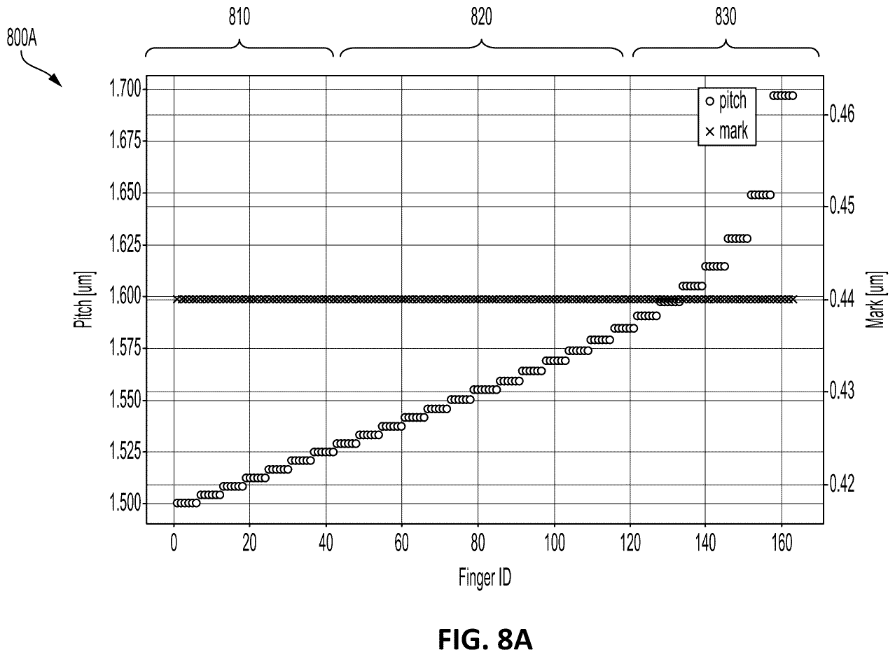

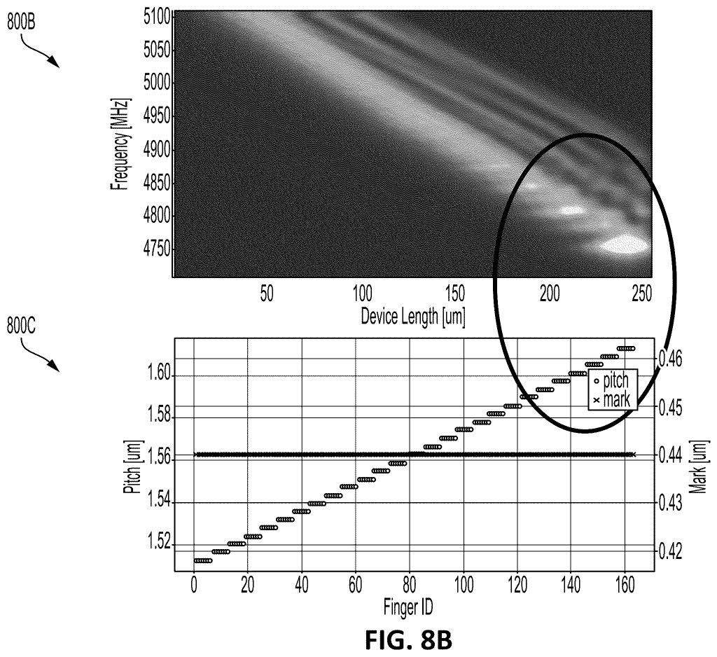

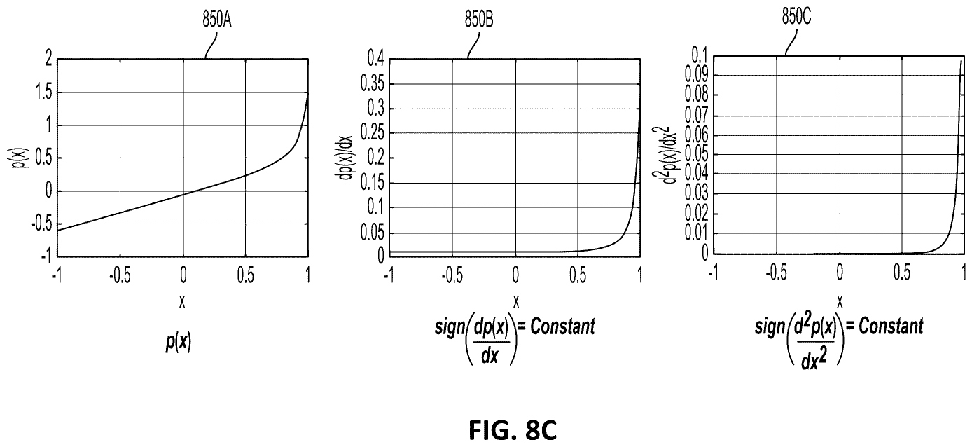

FIG. 8A is a graph 800A of an IDT chirping profile as a function of position along a length of an IDT according to another exemplary aspect. Again, the X axis represents the position along the length of the IDT, which can be denoted as “x” in an exemplary aspect. Thus, x ranges from −1 to +1, with X=0 at a center position of the IDT. The Y axis represents relative IDT chirping for a given position along the length of the IDT. Specifically, in the exemplary aspect, the Y axis represents relative IDT chirping for the pitch (in μm) from a range of 1.500 μm to 1.700 μm. In this exemplary aspect, the mark is shown to be constant at 0.44 μm along the length of the IDT. However, in another exemplary aspect, the mark can have a linear gradient that is opposite the variance of the pitch (at least in the linear segments) to balance the chirping profile, except where the pitch increases exponentially towards the end of the IDT.

Thus, according to the exemplary aspect in FIG. 8A, the chirping profile is asymmetric and provides a large chirp gradient (e.g., a localized curvature of a selected subsection of the IDT) only at a hotspot of the spurious mode. In other words, the pitch chirping of the IDT is substantially linear, except that the nonlinear section is confined to a subsection of the IDT. It is noted that the term “substantially linear” indicates that the pitching chirping, for example, increases in a linear manner taking into account possible variations of this linearity due to manufacturing tolerances (e.g., ±5%). Moreover, similar to the graph 700A of FIG. 7A, the IDT profile shown in FIG. 8A can be divided into three sections 810, 820 and 830. That is, an acoustic resonator is provided that includes a piezoelectric layer and an IDT on a surface of the piezoelectric layer. In this aspect, the IDT can have a plurality of interleaved fingers that alternately extend from a first busbar and a second busbar, such as busbars 632 and 634.

The IDT can comprise at least three sections that includes a first section 810, a last section 830 and a center section 820 disposed between the first section 810 and the last section 830 in a length direction of the IDT. Alternatively, the three sections can be considered a first section 810, a second section 820 and a third section 830. Moreover, it should be appreciated that each of first section 810, second section 820 and third section 830 can be divided into a one or plurality of subsections. While the pitch and/or mark of each section is chirped as described herein, the subsections can have a constant pitch or mark within each section. In other words, each of first section 810, second section 820 and third section 830 can comprise a plurality of subsections that each have at least three interleaved fingers having at least one of a constant pitch and a constant mark therein. In other words, each subsection can have three or more interleaved fingers having the same pitch and/or the same mark within that respective subsection. An exemplary aspect is shown in FIG. 8A in which each small horizontal dashed line of the pitch is shown to be constant for a plurality of fingers.

According to the exemplary aspect, the chirping profile of the IDT in FIG. 8A is configured such that the pitch (or mark profile) of the center section 720 (e.g., a middle of the IDT) is substantially linear (e.g., has a first slope of the variance) and the variation of at least one of the pitch of the last section 730 increases (e.g., a second slope of the variance) as the last section 730 extends away from the center section 720 in the length direction of the IDT. The chirping profile of the first section 710 is shown to be substantially linear in this exemplary aspect. As such, first section 710 and center section 720 can be considered a single section having the same linear chirping profile in an exemplary aspect. In this aspect, the first section 710 and/or center section 720 have a pitch (or mark) have a first profile or slope (e.g., linearly or substantially linearly) and the third or last section 730 has a second profile or slope (e.g., exponentially) that is different and typically greater than the first profile or slope as described herein and shown, for example, in FIG. 8A.

FIG. 8B illustrates a plot 800B showing acoustic intensity relative to a graph 800C illustrating which subsection(s) of the IDT should have the nonlinear chirping configuration according to the exemplary aspect described herein. Importantly, the subsection of the IDT that should have the nonlinear chirping profile is determined based on confining the acoustic energy to one spatial segment of the IDT due to a chirp. In other words, the “hot spot” shown in plot 800B illustrates that the chirp profile change should be intensified to reduce the magnitude of the hot spot, which is identified by the circle. Based on the hot spot that would be otherwise be experienced by an IDT having a linear IDT chirping profile, a subsection of the IDT can be chirped to have a rapid increase in slope at edge, which is shown as the third or last section 830 in FIG. 8A. In each of the examples in graphs 800A and 800C, the total number of fingers of the IDT is shown to be 160 with the section 830 starting at approximately the 120th finger of the IDT. Thus, the number of interleaved fingers of the section having the nonlinear chirping profile (e.g., section 83) comprises 25% or less of a total number of fingers of the plurality of interleaved fingers of the IDT in the exemplary aspect.

FIG. 8C illustrates three graphs showing the pitch profile p(x), the first derivative and the second derivative of the profile p(x) of the IDT having the chirping profile shown in the graph 800A. In general, the first derivative of a function gives the slope of the graph at a point, while the second derivative indicates whether the curve is concave up or concave down at that point. If the second derivative is positive, the graph is bending upwards at that point, and if it is negative, the graph is concave down. The second derivative also indicates the shape of a graph and the concavity and inflection points of a function's graph.

In FIG. 8C, the pitch profile p(x) is shown as graph 850A, the first derivative of the pitch profile p(x) is shown as graph 850B, and the second derivative of the pitch profile p(x) is shown as graph 850C. As noted above, the pitch profile p(x) shown in graph 850A can generally correspond to that of graph 800A in FIG. 8A. Moreover, the first derivative shown in the graph 850B illustrates that the pitch profile p(x) is monotonic (e.g., that it is entirely non-decreasing) and that the sign can be positive or negative. As used herein, a pitch profile may be “monotonic” if it is entirely non-decreasing, or entirely non-increasing. A pitch profile that increases monotonically does not exclusively have to increase, but it may not decrease, and vis versa for a pitch profile that decreases monotonically. Finally, the second derivative shown in the graph 850C illustrates that the concavity is the same sign. Thus, according to an exemplary aspect, the last or third section 830 of the IDT has a chirping profile that is configured such that a first mathematical derivative of the non-linear chirping profile is a same sign that increases monotonically, and a second mathematical derivative of the non-linear chirping profile is nonzero and a same sign that is increases exponentially. Moreover, the first section 810 and the center or second section 820 has chirping profile with a variation that is substantially linear along the respective lengths of each section as described above. It is noted that the first and second derivatives of the graphs plotting the exemplary nonlinear chirping profiles are generally estimated and the actual chirping profiles may vary in practice taking into accounting manufacturing tolerances, for example.

It is also reiterated that while three sections 810, 820 and 830 are shown in the exemplary aspect, the IDT in this instance generally has an asymmetric chirping profile, such that a variation of the pitch (and/or also the mark) of one section (e.g., the last section 830) of a plurality of sections is non-linear across the length of the that section. Moreover, a second section (e.g., the center section 820 or the combined first and center sections 810 and 820) of the plurality of sections of the IDT has a pitch profile that is substantially linear and different than the asymmetric chirping profile of the one section.

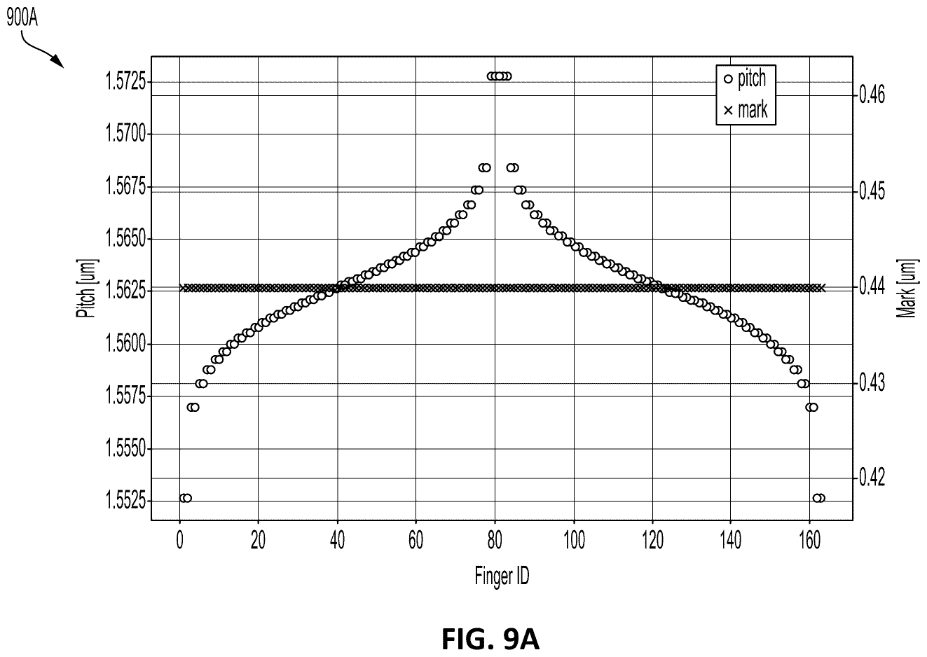

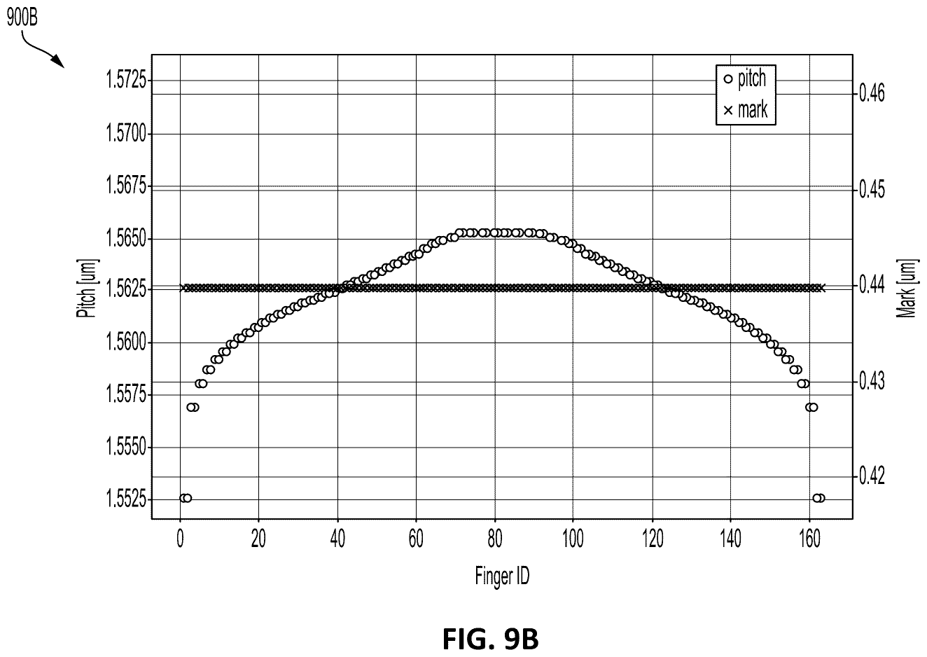

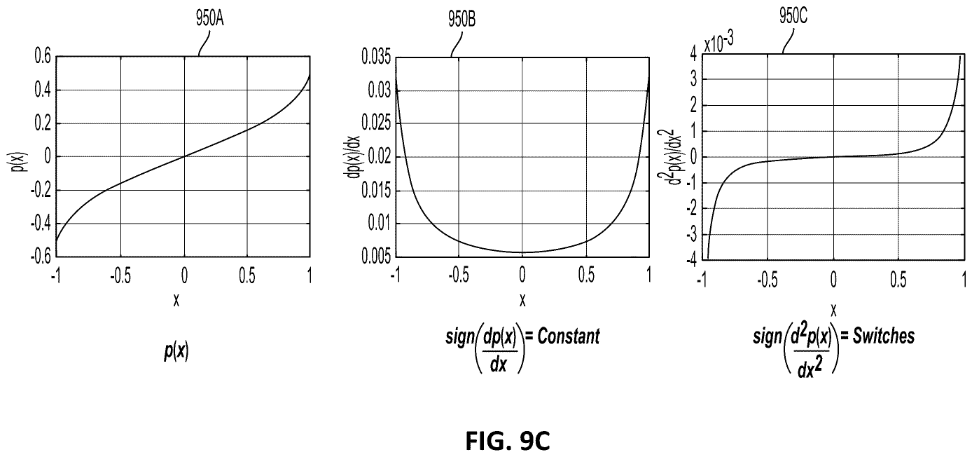

FIG. 9A is a graph 900A of an IDT chirping profile as a function of position along a length of an IDT according to another exemplary aspect. Again, the X axis represents the position along the length of the IDT, which can be denoted as “x” in an exemplary aspect. Thus, x ranges from −1 to ±1, with X=0 at a center position of the IDT. In this example, the IDT has approximately 160 fingers, so X=0 would be at approximately finger ID 80. Moreover, the Y axis represents relative IDT chirping for a given position along the length of the IDT. Specifically, in the exemplary aspect, the Y axis represents relative IDT chirping for the pitch (in μm and denoted by a plurality of “0s”) from a range of 1.5525 μm to 1.5725 μm. In this exemplary aspect, the mark (denoted by a plurality of “Xs”) is shown to be constant at 0.44 μm along the length of the IDT, but the mark can vary linearly or nonlinearly in alternative aspects.

Accordingly, the hyperbolic or nonlinear profile described above with respect to FIGS. 7A and 7B is not necessarily monotonic. Instead, graph 900A illustrates a hyperbolic triangle that includes a large gradient at the edges to provide good spur suppression at local hot spots and also provides symmetry for good harmonic cancellation properties. As also shown the largest pitch is at the center section of the IDT and exponentially decreases towards the outer edges of the IDT.

Thus, the exemplary embodiment shown in FIG. 9A provides for an IDT with at least a first section and second section, generally shown as the left and right sides of the “finger ID”. In this aspect, the interleaved fingers of each of the first section and the second section have an asymmetric chirping profile, such that a variation of at least one of a mark and a pitch is non-linear across the length of the respective section. Moreover, the variation of at least one of the pitch and the mark of each of the first and second sections increases exponentially as the respective length of each of the first and second sections extend towards each other (e.g., towards the peak or center of the IDT around finger ID 80, for example). As a result, the IDT collectively (e.g., in its entirety) includes a symmetric chirping profile, which is shown as a hyperbolic triangle in the exemplary aspect.

FIG. 9B is a graph of an IDT chirping profile as a function of position along a length of an IDT according to another exemplary aspect. It is noted that the graph 900B provides an IDT chirping profile that is similar to the graph 900A in which the profile is a function of position along a length of an IDT. Again, the mark (denoted by a plurality of “Xs”) is shown to be constant at 0.44 μm along the length of the IDT, but the mark can vary linearly or nonlinearly in alternative aspects.

Accordingly, the hyperbolic or nonlinear profile described above with respect to FIGS. 7A and 7B is not necessarily monotonic. However, instead of the hyperbolic triangle of graph 900A, the graph 900B includes a pitch distribution that flattens (approximately to zero) in the middle of the IDT length and then includes a large gradient at the edges to provide good spur suppression at local hot spots and also provides symmetry for good harmonic cancellation properties. Again, the largest pitch is at the center section of the IDT and exponentially decreases towards the outer edges of the IDT.

Thus, the exemplary embodiment shown in FIG. 9B provides for an IDT with at least a first section and second section, generally shown as the left and right sides of the “finger ID”. In this aspect, the interleaved fingers of each of the first section and the second section have an asymmetric chirping profile, such that a variation of at least one of a mark and a pitch is non-linear across the length of the respective section. Moreover, the variation of at least one of the pitch and the mark of each of the first and second sections increases as the respective length of each of the first and second sections extend towards each other (e.g., towards the center of the IDT around finger ID 80, for example) and then flattens out before decreasing towards the edges. As a result, the IDT collectively (e.g., in its entirety) includes a symmetric chirping profile, which is shown essentially as an upside-down U-shape in the exemplary aspect.

It is noted that while the graphs 900A and 900B show the pitch being smallest at the outer edges of the IDT, this configuration can be inverted. In other words, the pitches at the out edges of the IDT can be largest in an alternative aspect, such that the profiles in graphs 900A and 900B can effectively be flipped upside down.

FIG. 9C illustrates three graphs showing the pitch profile p(x), the first derivative and the second derivative of the profile p(x) of the IDT having the chirping profile shown in the graph 900A. More particularly, the pitch profile p(x) is shown as graph 950A, the first derivative of the pitch profile p(x) is shown as graph 950B, and the second derivative of the pitch profile p(x) is shown as graph 950C. In an exemplary aspect, the pitch profile p(x) shown in graph 950A corresponds to that of the concave out line 740B in FIG. 7A. Moreover, the first derivative shown in the graph 950B illustrates that the pitch profile p(x) is monotonic and that the sign can be positive or negative. The second derivative shown in the graph 950C illustrates that the concavity is the same sign. It should be appreciated that the chirping profile is not necessarily symmetric about the center point of the IDT. It is also again noted that the first and second derivatives of the graphs plotting the exemplary nonlinear chirping profiles are generally estimated and the actual chirping profiles may vary in practice taking into accounting manufacturing tolerances, for example.

According to the exemplary configurations, the chirping (or variance) of the pitch and/or the mark of the IDT of a bulk acoustic resonator can be configured to suppress undesirable spurious magnitudes for small signal or large signal performance gains. However, as the magnitude of chirping increases, both the problematic spur and main A1 mode are degraded. Thus, to counteract this effect, the degradation of the A1 mode can be minimized by utilizing balanced chirping. For example, if the main mode has frequency response to mark and pitch as fᵣ (p,m), and a chirping profile p(x) is selected, then a corresponding chirp profile m(x) can be selected such that fᵣ (p(x),m(x)) is constant to minimize the main mode degradation. Thus, even when balanced chirping is considered, it is beneficial to utilize a chirping profile that maximizes the spurious suppression at minimal cost to the main A1 mode as would be appreciated to one skilled in the art.

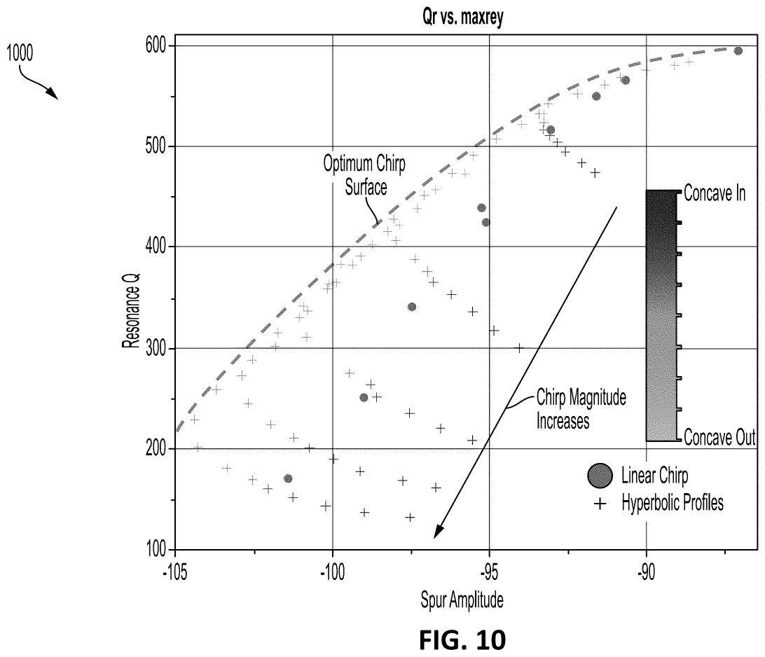

FIG. 10 illustrates a graph 1000 that illustrates the impact on the A1 mode measured as the reduction in resonance Q that trades with reduction in spur amplitude. The X axis of graph 1000 illustrates the spur amplitude and the Y axis illustrates the resonance Q. The optimum chirp surface is shown as a dashed line (i.e., to maximize resonance Q for a given spurious reduction). The linear chirp is shown as “o” references and the hyperbolic chirping profile (i.e., concave in and concave out profiles) are shown as “+” references with concave in being in dark grey and concave out being in light grey. As clearly shown the concave out chirping profile most closely matches the optimum chirp surface.

In general, it should be appreciated that the nonlinear chirping profile described herein can be combined with a fully or partially balanced profile and that the nonlinear chirping profiles can be used for either mark or pitch, although a chirped pitch is described above with respect to FIG. 8A, for example. Moreover, the precise optimum shape (in terms of spur suppression) may depend on the particulars of the spurious mode (e.g., A0ₙ modes versus S0ₙ modes).

Throughout this description, the embodiments and examples shown should be considered as exemplars, rather than limitations on the apparatus disclosed or claimed. Although many of the examples presented herein involve specific combinations of elements, it should be understood that those acts and those elements may be combined in other ways to accomplish the same objectives.

Finally, as used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

What is claimed:

1. An acoustic resonator comprising:
a piezoelectric layer;
an interdigital transducer (IDT) on a surface of the piezoelectric layer, the IDT having a plurality of interleaved fingers that alternately extend from a first busbar and a second busbar,
wherein the IDT comprises at least three sections that includes a first section, a last section and a center section disposed between the first and last sections in a length direction of the IDT,
wherein each of the at least three sections comprise a respective length that includes at least two pairs of interleaved fingers,
wherein at least one section of the first section and the last section of the IDT comprises a chirping profile that is non-linear, such that a variation of at least one of a mark and a pitch of the at least one section is non-linear across the length of the at least one section, the mark being a width of the at least two pairs of interleaved fingers and the pitch being a center-to-center spacing between each pair of interleaved fingers, and
wherein a first mathematical derivative of the non-linear chirping profile of the at least one section is a same sign that increases monotonically, and a second mathematical derivative of the non-linear chirping profile of the at least one section is nonzero and a same sign that is increases exponentially.

2. The acoustic resonator according to claim 1, wherein both the first section and the last section of the IDT comprise a non-linear chirping profile that is concave out, such that the variation of the at least one of the mark and the pitch of each of the first and last sections is flatter as the respective section extends towards the center section and steeper as the respective section extends away from the center section.

3. The acoustic resonator according to claim 2, wherein the variation of the at least one of the mark and the pitch of both the first section and last section is represented by A(x), where:
$$A ( x ) = \frac{A}{2} a tanh ( x tanh ( 2 π k ) ) ,$$
where k>0 and measures a curvature of the non-linear chirping profile, and x is between −1 and +1.

4. The acoustic resonator according to claim 1, wherein both the first section and the last section of the IDT comprise a non-linear chirping profile that is concave in, such that the variation of the at least one of the mark and the pitch of each of the first and last sections is steeper towards the center section and flatter as the respective section extends away from the center section.

5. The acoustic resonator according to claim 4, wherein the variation of the at least one of the mark and the pitch of both the first section and last section is represented by A(x), where:
$$A ( x ) = \frac{A}{2} \frac{tanh ( 2 π kx )}{tanh ( 2 π k )} ,$$
where k>0 and measures a curvature of the non-linear chirping profile, and x is between −1 and +1.

6. The acoustic resonator according to claim 1, wherein each of the center section and the at least one section comprise a plurality of subsections that each have at least three interleaved fingers that have at least one of a constant pitch and a constant mark therein.

7. The acoustic resonator according to claim 1, wherein a number of interleaved fingers of the at least one section comprises approximately 25% or less of a total number of fingers of the plurality of interleaved fingers of the IDT.

8. The acoustic resonator according to claim 7, wherein the variation of the pitch of the at least one section increases exponentially and the variation of the pitch of the center section is comparatively linear relative to the variation of pitch of the at least one section.

9. The acoustic resonator according to claim 8, wherein the mark is substantially constant across the length of the IDT.

10. The acoustic resonator according to claim 8, wherein the center section comprises a chirping profile that is substantially linear.

11. An acoustic resonator comprising:
a piezoelectric layer;
an interdigital transducer (IDT) on a surface of the piezoelectric layer, the IDT having a plurality of interleaved fingers that alternately extend from a first busbar and a second busbar,
wherein the IDT comprises a plurality of sections that each have a respective length that includes at least two pairs of interleaved fingers,
wherein the IDT has an asymmetric chirping profile, such that a variation of at least one of a mark and a pitch of a first section of the plurality of sections is non-linear across the length of the first section, the mark being a width of the at least two pairs of interleaved fingers and the pitch being a center-to-center spacing between each pair of interleaved fingers, and
wherein the variation of the at least one of the mark and the pitch has a less than 25% effect on a primarily excited main acoustic mode of the acoustic resonator in comparison to a 1:1 effect of at least one of a pitch and a mark on a mode other than the primarily excited main acoustic mode.

12. The acoustic resonator according to claim 11, wherein a second section of the plurality of sections of the IDT has a pitch or mark profile that is substantially linear and different than the asymmetric chirping profile of the first section.

13. The acoustic resonator according to claim 12, wherein the plurality of sections of the IDT comprise the first section, the second section and a third section, with the second section being a center section between the first and third sections in a length direction of the IDT.

14. The acoustic resonator according to claim 13, wherein both the first section and the third section of the IDT comprise a non-linear chirping profile that is concave out, such that the variation of the at least one of the mark and the pitch of each of the first and third sections is flatter as the respective section extends towards the center section and steeper as the respective section extends away from the center section.

15. The acoustic resonator according to claim 14, wherein the variation of the at least one of the mark and the pitch of both the first section and third section is represented by A(x), where:
$$A ( x ) = \frac{A}{2} a tanh ( x tanh ( 2 π k ) ) ,$$
where k>0 and measures a curvature of the non-linear chirping profile, and x is between −1 and +1.

16. The acoustic resonator according to claim 13, wherein both the first section and the third section of the IDT comprise a non-linear chirping profile that is concave in, such that the variation of the at least one of the mark and the pitch of each of the first and third sections is steeper towards the center section and flatter as the respective section extends away from the center section.

17. The acoustic resonator according to claim 16, wherein the variation of the at least one of the mark and the pitch of both the first section and third section is represented by A(x), where:
$$A ( x ) = \frac{A}{2} \frac{tanh ( 2 π kx )}{tanh ( 2 π k )} ,$$
where k>0 and measures a curvature of the non-linear chirping profile, and x is between −1 and +1.

18. The acoustic resonator according to claim 13, wherein:
the pitch or mark profile of the second section is substantially linear and the variation of at least one of a mark and a pitch of the first section increases as the first extends away from the second section in a length direction of the IDT, and
a first mathematical derivative of the asymmetric chirping profile of the first section is a same sign that increases monotonically, and a second mathematical derivative of the asymmetric chirping profile of the first section is nonzero and a same sign that is increases exponentially.

19. The acoustic resonator according to claim 12,
wherein a number of interleaved fingers of the first section comprises approximately 25% or less of a total number of fingers of the plurality of interleaved fingers of the IDT, and
the variation of the pitch of the at first section increases exponentially and the variation of the pitch of the second section is comparatively linear relative to the variation of pitch of the at least one section.

20. An acoustic resonator comprising:
a piezoelectric layer;
an interdigital transducer (IDT) on a surface of the piezoelectric layer, the IDT having a plurality of interleaved fingers that alternately extend from a first busbar and a second busbar,
wherein the IDT comprises a first section and a second section that each have a respective length that includes at least two pairs of interleaved fingers,
wherein the interleaved fingers of each of the first section and the second section have an asymmetric chirping profile, such that a variation of at least one of a mark and a pitch is non-linear across the length of the respective section, the mark being a width of the at least two pairs of interleaved fingers and the pitch being a center-to-center spacing between each pair of interleaved fingers, and
wherein the variation of the at least one of the pitch and the mark of each of the first and second sections increases exponentially as the respective length of each of the first and second sections extend towards each other, such that the IDT collectively including the first and second sections has a symmetric chirping profile.
